(19) United States
(12) Patent Application Publication
(10) Pub. No.: US 2025/0159872 A1
(43) Pub. Date: May 15, 2025

(54) SEMICONDUCTOR DEVICE AND FABRICATION METHOD THEREOF, MEMORY SYSTEM

(71) Applicant: YANGTZE MEMORY TECHNOLOGIES CO., LTD., Wuhan (CN)

(72) Inventors: Yaqin LIU, Wuhan (CN); Wei LIU, Wuhan (CN); ZhiLiang XIA, Wuhan (CN); ZongLiang HUO, Wuhan (CN); Yuancheng YANG, Wuhan (CN); DongXue ZHAO, Wuhan (CN)

(21) Appl. No.: 18/746,811

(22) Filed: Jun. 18, 2024

(30) Foreign Application Priority Data
Nov. 14, 2023 (CN) 202311530867.3

(51) Int. Cl. H10B 12/00; G11C 11/408; G11C 11/4091

(52) U.S. Cl. CPC H10B 12/50; H10B 12/09; H10B 12/315; H10B 12/33; G11C 11/4085; G11C 11/4091

(57) ABSTRACT

Implementations of the present application provide a semiconductor device, a fabrication method thereof and a memory system. The semiconductor device includes a first semiconductor structure and a second semiconductor structure. The second semiconductor structure is disposed on a side of the first semiconductor structure in the first direction and in direct contact with the first semiconductor structure, wherein the second semiconductor structure includes a plurality of memory cells, the first semiconductor structure includes a first peripheral circuit connected with the plurality of memory cells, and in the plane perpendicular to the first direction, at least a portion of the first peripheral circuit is located directly below the plurality of memory cells, wherein the first peripheral circuit includes at least one of a driving structure and a sensing structure.

### CROSS-REFERENCE TO RELATED APPLICATIONS

This application claims priority to and the benefit of Chinese Patent Application No. 202311530867.3, filed on Nov. 14, 2023, which is hereby incorporated by reference in its entirety.

### TECHNICAL FIELD

The present application relates to the field of semiconductor design and fabrication, and more particularly to a semiconductor device, a fabrication method of semiconductor device and a memory system.

### BACKGROUND

With the rapid development of semiconductor technology, how to improve the storage density of semiconductor devices such as DRAMs, optimize their comprehensive performance and reduce the process costs is one of the important study directions in the industry.

### SUMMARY

The present application provides a fabrication method of a semiconductor device, a semiconductor device and a memory system that may at least in part address the above-described problems with the prior art or other problems in the art.

In some implementations, the present application provides a semiconductor device comprising: a first semiconductor structure; and a second semiconductor structure disposed on a side of the first semiconductor structure in the first direction and in direct contact with the first semiconductor structure, wherein the second semiconductor structure comprises a plurality of memory cells, the first semiconductor structure includes a first peripheral circuit connected with the plurality of memory cells, and in the plane perpendicular to the first direction, at least a portion of the first peripheral circuit is located directly below the plurality of memory cells, wherein the first peripheral circuit comprises at least one of a driving structure and a sensing structure.

In an implementation of the present application, the first semiconductor structure further comprises a first interconnect structure, wherein the first interconnect structure is located on a side of the first peripheral circuit close to the second semiconductor structure in the first direction and connects the first semiconductor structure and the second semiconductor structure; and the second semiconductor structure further comprises a power layer and a second interconnect structure, wherein the second interconnect structure connects the power layer and the first semiconductor structure.

In an implementation of the present application, the power layer is located on a side of the plurality of memory cells away from the first semiconductor structure in the first direction.

In an implementation of the present application, the semiconductor structure comprises a word line and a bit line connected with the plurality of memory cells; and the driving structure comprises a word line driving structure connected with the word line, and the sensing structure comprises a bit line sensing amplifying structure connected with the bit line.

In an implementation of the present application, the semiconductor structure further comprises a word line contact structure connecting the word line and the word line driving structure and a bit line contact structure connecting the bit line and the bit line sensing amplifying structure, wherein at least one of the word line contact structure and the bit line contact structure extends in the first direction.

In an implementation of the present application, the bit line extends in a second direction, the word line extends in a third direction, wherein the first direction, the second direction and the third direction are perpendicular to each other, wherein in a plane parallel to the second direction and the third direction, the driving structures and the sensing structures are alternately disposed in the second direction or the third direction.

In an implementation of the present application, the bit line extends in a second direction, the word line extends in a third direction, wherein the first direction, the second direction and the third direction are perpendicular to each other, wherein in a plane parallel to the second direction and the third direction, at least one of: a plurality of the driving structures are distributed symmetrically; or a plurality of the sensing structures are distributed symmetrically.

In an implementation of the present application, at least one of the plurality of memory cells comprises a vertical transistor and a storage cell connected with the vertical transistor, wherein in the first direction, the vertical transistor is closer to the first semiconductor structure than the storage cell.

In an implementation of the present application, the vertical transistor comprises at least one of a gate all around transistor, a multi-gate transistor and a single gate transistor.

In an implementation of the present application, the vertical transistor comprises a thin film transistor.

In an implementation of the present application, the vertical transistor comprises a semiconductor body extending in the first direction, wherein the semiconductor body comprises an oxide semiconductor layer.

In some implementations, the present application provides a fabrication method of a semiconductor device comprising: forming a first semiconductor structure on a substrate; and forming a second semiconductor structure in direct contact with the first semiconductor structure on the first semiconductor structure, wherein the second semiconductor structure comprises a plurality of memory cells, the first semiconductor structure comprises a first peripheral circuit connected with the plurality of memory cells; and in the plane parallel to the substrate, the first peripheral circuit is located directly below the plurality of memory cells, wherein the first peripheral circuit comprises at least one of a driving structure and a sensing structure.

In an implementation of the present application, forming the second semiconductor structure in direct contact with the first semiconductor structure on the first semiconductor structure comprises: forming a first dielectric layer on the first semiconductor structure; forming a storage cell on the first dielectric layer; forming a semiconductor body connected with the storage cell and a gate structure connected with the semiconductor body on the storage cell, wherein the semiconductor body extends in a first direction perpendicular to the substrate.

In an implementation of the present application, forming the second semiconductor structure in direct contact with the first semiconductor structure on the first semiconductor structure comprises: forming a bit line on the first semiconductor structure; forming a semiconductor body and a gate structure connected with the semiconductor body on the bit line, wherein the semiconductor body extends in a first direction perpendicular to the substrate; and forming a storage cell connected with the semiconductor body on the semiconductor body.

In an implementation of the present application, the semiconductor body is formed with low temperature deposition process, wherein a process temperature T for the low temperature deposition satisfy: 200° C.≤T≤300° C.

In some implementations, the present application provides a semiconductor device comprising: a first semiconductor structure; and a semiconductor body disposed on a side of the first semiconductor structure in a first direction, wherein the semiconductor body comprises a first section and a second section connected with each other; the first section extends in the first direction; and the second section extends in a direction perpendicular to the first direction and directly contacts the first semiconductor structure.

In an implementation of the present application, the first semiconductor structure comprises a first peripheral circuit, wherein at least a portion of the first peripheral circuit is located directly below the plurality of semiconductor bodies, and the first peripheral circuit comprises at least one of a driving structure and a sensing structure.

In an implementation of the present application, the semiconductor structure further comprises a first interconnect structure, a power layer and a second interconnect structure, wherein the first interconnect structure is located on a side of the first peripheral circuit close to the semiconductor body in the first direction; the power layer is located on a side of the semiconductor body away from the first semiconductor structure in the first direction; and the second interconnect structure connects the power layer and the first semiconductor structure.

In an implementation of the present application, the first section comprises a first end and a second end disposed oppositely in the first direction and sides between the first end and the second end, wherein the semiconductor structure further comprises a gate structure located on a side of the semiconductor body in the second direction and a bit line connecting the first end or the second end, wherein the second direction are perpendicular to the first direction.

In an implementation of the present application, a plurality of gate structures close to each other in the second direction are distributed in mirror symmetry in the first direction.

In an implementation of the present application, a plurality of semiconductor bodies close to each other in the second direction are distributed in mirror symmetry in the first direction.

In an implementation of the present application, the semiconductor structure further comprises a word line connecting the gate structures and extending in a third direction, wherein the first direction, the second direction and the third direction are perpendicular to each other; and the first semiconductor structure comprises a first peripheral circuit, wherein the first peripheral circuit comprises at least one of a driving structure and a sensing structure, wherein the driving structure comprises a word line driving structure connected with the word line, and the sensing structure comprises a bit line sensing amplifying structure connected with the bit line.

In an implementation of the present application, the semiconductor structure further comprises a word line contact structure connecting the word line and the word line driving structure and a bit line contact structure connecting the bit line and the bit line sensing amplifying structure, wherein at least one of the word line contact structure and the bit line contact structure extends in the first direction.

In an implementation of the present application, in a plane parallel to the second direction and the third direction, the driving structures and the sensing structures are alternately disposed in the second direction or the third direction.

In an implementation of the present application, in a plane parallel to the second direction and the third direction, at least one of: a plurality of the driving structures are distributed symmetrically; or a plurality of the sensing structures are distributed symmetrically.

In an implementation of the present application, the semiconductor body comprises an oxide semiconductor layer.

In some implementations, the present application provides a memory system comprising the semiconductor device provided in an implementation of the present application and a controller coupled with the semiconductor device and configured to store data into the semiconductor device.

With the semiconductor device and the fabrication method thereof, as well as the memory system provided according to at least one implementation of the present application, the semiconductor device comprises a first semiconductor structure and a second semiconductor structure over and in direct contact with the first semiconductor structure, wherein the second semiconductor structure comprises a plurality of memory cells, the first semiconductor structure comprises a first peripheral circuit connected with the plurality of memory cells, and at least a portion of the first peripheral circuit is located directly below the plurality of memory cells. In other words, the second semiconductor structure including the plurality of memory cells is formed on a peripheral circuit wafer and a portion of the peripheral circuit may be located directly below the plurality of memory cells.

### BRIEF DESCRIPTION OF DRAWINGS

Through reading the detailed description of non-limiting implementations made with reference to the following figures, other features, purposes and advantages of the present application will become more apparent. In the drawings:

FIG. 1 is a sectional view of a semiconductor device according to an implementation of the present application;

FIG. 2 is a sectional view of a semiconductor device according to an implementation of the present application;

FIG. 3 is a partial sectional view of a second semiconductor structure according to an implementation of the present application;

FIG. 4 is a partial top view of a second semiconductor structure according to an implementation of the present application;

FIG. 5 is a partial sectional view of a second semiconductor structure according to another implementation of the present application;

FIG. 6 is a partial top view of a second semiconductor structure according to another implementation of the present application;

FIG. 7 is a partial sectional view of a second semiconductor structure according to another implementation of the present application;

FIG. 8 is a partial top view of a second semiconductor structure according to another implementation of the present application;

FIG. 9 is a top view of a first peripheral circuit according to an implementation of the present application;

FIG. 10 is a top view of a first peripheral circuit according to another implementation of the present application;

FIG. 11 is a top view of a first peripheral circuit according to another implementation of the present application;

FIG. 12 is a flow chart of a method of fabricating a semiconductor device according to an example implementation of the present application;

FIGS. 13-33 are process diagrams of a fabrication method of a semiconductor device according to an implementation of the present application respectively;

FIGS. 34-38 are process diagrams of a fabrication method of a semiconductor device according to another implementation of the present application respectively; and

FIG. 39 is a structure diagram of a memory system according to an implementation of the present application.

### DETAILED DESCRIPTION

For better understanding of the application, some implementations of the application will be described in more detail with reference to accompanying drawings. It is to be appreciated that the detailed description is only for the purpose of explaining example implementations of the application and will in no way limit the scope of the application. Throughout the specification, identical reference numerals refer to identical elements. The expression “and/or” covers any and all combinations of one or more of the listed relevant items.

It is to be noted that, throughout this specification, expressions such as “first”, “second”, “third” and the like are only used to distinguish one feature from another, and mean no limitation for any feature especially in any order. Therefore, a first semiconductor structure as discussed in the present application may also be referred to as a second semiconductor structure and vice versa, without departing from the teachings of the present application.

In the figures, thicknesses, dimensions and shapes of components have been somewhat adjusted for easy illustration. The figures are only examples and not strictly drawn to scale. As used herein, terms “approximate”, “about” and the like indicate approximation instead of degrees and are intended to mean inherent variations in measurement values or calculated values, which can be appreciated by those of ordinary skills in the art.

It is also to be appreciated that, as used herein, expressions such as “include”, “comprise”, “have” and/or “contain” are not exclusive but open, i.e., they indicate existence of the stated feature, element and/or component, but will not exclude existence of one or more other features, elements, components and/or any combinations thereof. Furthermore, when the expression such as “at least one of” precedes a list of features, it modifies all the listed features instead of any individual ones. Furthermore, as used in the description of an implementation of the present application, the term “may” is used to indicate “one or more implementations of the present application”. Also, the term “example” means to be exemplary or illustrative.

All the terms (including engineering terms and scientific and technical terms) used herein have the same meanings as those commonly understood by those of ordinary skills in the art, unless otherwise specified. It is also to be appreciated that the terms defined in common dictionaries should be interpreted to have the meanings consistent with their contexts in pertinent arts and should not be interpreted too ideally or formally, unless otherwise specified explicitly in the application.

It is to be noted that implementations of the application and features thereof may be combined where there are no conflicts. Furthermore, operations contained in a method described in the application may not necessarily be performed in the described order and instead may be performed in any other order or in parallel, unless there is an explicit definition or any conflict with the context.

Moreover, as used in the application, the term “connect” or “couple” may indicate direct or indirect contact between corresponding components, unless it is otherwise defined or exact meaning can be derived from its context.

The application will be described in detail hereafter in connection with implementations with reference to accompanying drawings.

Dynamic random access memory (DRAM) is one of important storage components in an electronic system. Considering a DRAM as an example, a semiconductor device may include a memory cell consisting of a capacitor and a transistor, wherein a plurality of memory cells may be arranged in the form of a two-dimensional array. In order to further reduce the size of the two-dimensional array, the transistor may include a vertical gate transistor (VGT). In such a structure, the source and drain of the transistor are located on two ends in the extension direction of the channel of the transistor and the gate structure of the transistor is located on at least one side of the channel.

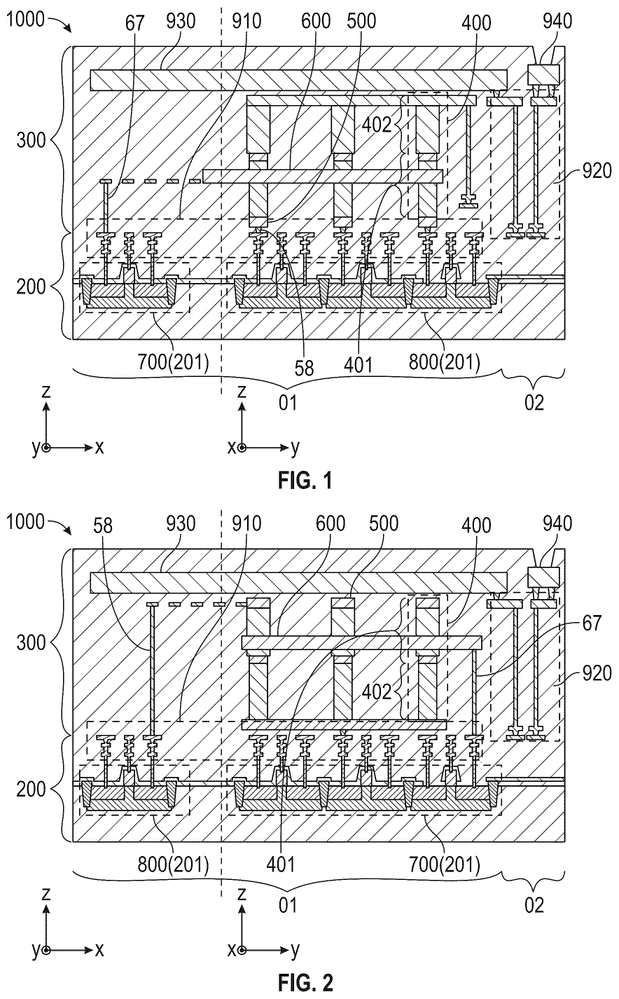

Some implementations of the present application provide a semiconductor device. FIG. 1 is a sectional view of a semiconductor device 1000 according to an implementation of the present application. FIG. 2 is a sectional view of a semiconductor device 1000 according to an implementation of the present application.

As shown in FIGS. 1-2, the semiconductor device 1000 includes a first semiconductor structure 200 and a second semiconductor structure 300. The second semiconductor structure 300 is disposed on a side of the first semiconductor structure 200 in the first direction (z direction) and in direct contact with the first semiconductor structure 200. The second semiconductor structure 300 includes a plurality of memory cells 400, and the first semiconductor structure 200 includes a first peripheral circuit 201 connected with the plurality of memory cells 400. In the plane perpendicular to z direction (such as x-y plane, wherein x direction, y direction and z direction are perpendicular to each other), at least a portion of the first peripheral circuit 201 is located directly below the plurality of memory cells 400, wherein the first peripheral circuit 201 includes at least one of a driving structure 700 and a sensing structure 800.

It is to be noted that in FIGS. 1-2 herein, only the numbers and locations of memory cells and peripheral circuit are illustrated. It is appreciated that the memory cells and peripheral circuit shown in the figures and related contents herein are only for the purpose of convenient illustration and the present application is not limited thereto. Those skilled in the art can modify the memory cells and peripheral circuit according to the concept of the present disclosure to achieve the same technical effect.

Furthermore, for convenience of observation, the cross section of the semiconductor device 1000 that is parallel to x-z plane and the cross section that is parallel to y-z plane are disposed on two sides of the dashed-dotted line respectively. In addition, one skilled in the art should understand that the term “directly below” in “at least a portion of the first peripheral circuit 201 is located directly below the plurality of memory cells 400” may be understood as that the disposing space for a portion of the first peripheral circuit overlaps with the disposing space for the plurality of memory cells in z direction so as to reduce the overall size of the semiconductor device and improve the storage density of the semiconductor device without impacting the comprehensive performance of the semiconductor device. In other words, the projection of the plurality of memory cells in x-y plane may approximately cover the projection of a portion of the first peripheral circuit in x-y plane; or put another way, at least a portion of the first region 01 in which the first peripheral circuit 201 is located may be located directly below the plurality of memory cells 400.

In some implementations, the plurality of memory cells such as the memory array of a semiconductor device and the peripheral circuit structure connected with the plurality of memory cells may be typically formed on two different wafers respectively such as the memory array wafer and the peripheral circuit wafer and then the peripheral circuit is bonded onto the memory array wafer via a process such as wafer bonding and the peripheral circuit is connected with the memory array circuit via for example connecting wires. However, as the structure of semiconductor device continuously develops towards high density, the area for peripheral circuit wafer has become a key factor that determines the overall chip size.

In at least one implementation of the present application, the second semiconductor structure is disposed on a side of the first semiconductor structure and in direct contact with the first semiconductor structure. In other words, the second semiconductor structure including a plurality of memory cells is formed on the peripheral circuit wafer. Therefore, there is no distortion caused by the above-described wafer bonding process and there is no limitation to the locations of connecting wires while reducing the fabrication costs of the semiconductor device. Additionally, disposing the first peripheral circuit including at least one of driving structure and sensing structure at least in part directly below the plurality of memory cells facilitates shortening the length of connecting wires between the first peripheral circuit and the plurality of memory cells, which in turn reduces the parasitic capacitance of connecting wires and improves the sensing tolerance and storage density of the semiconductor device.

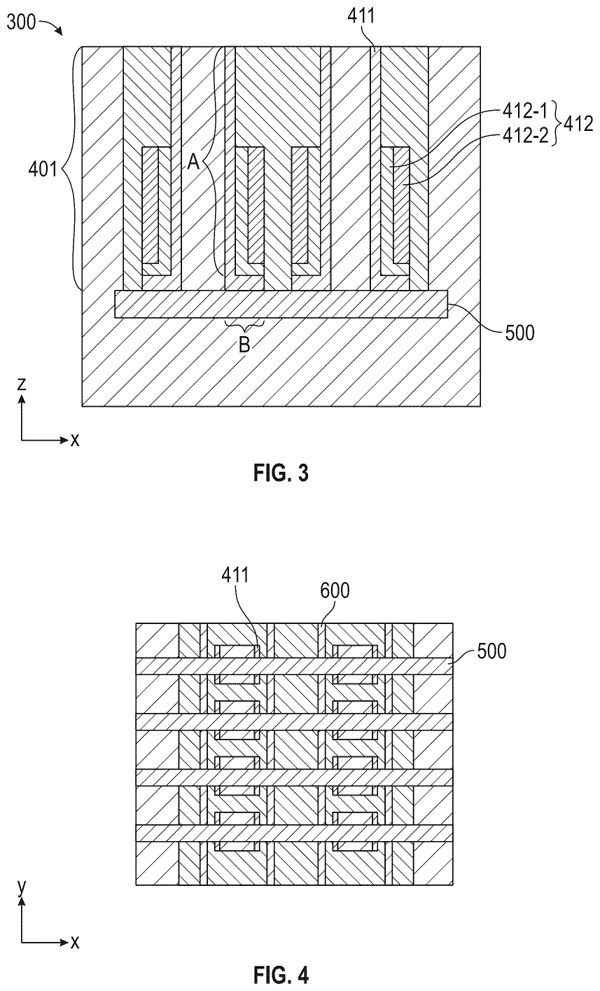

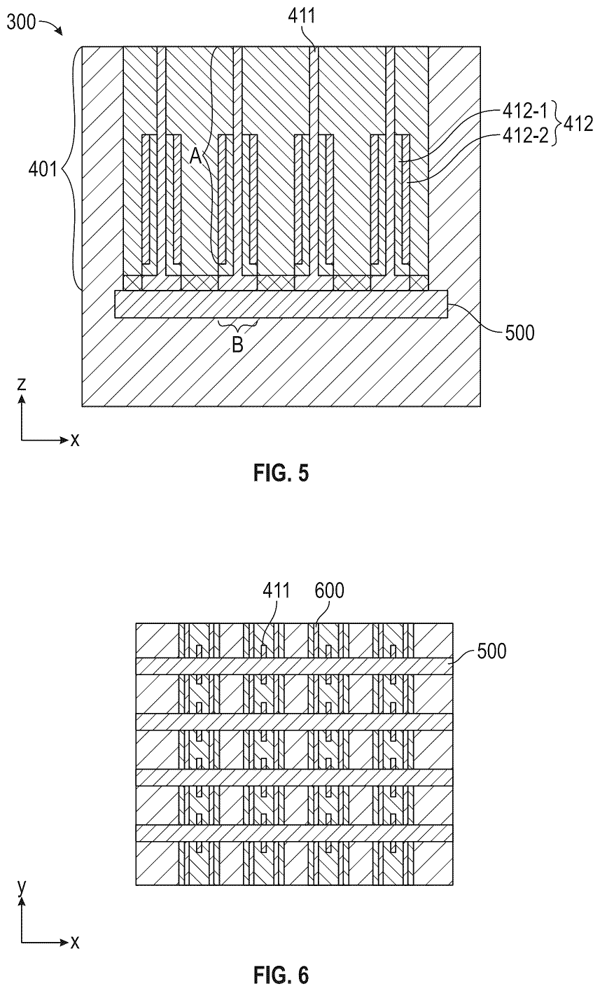

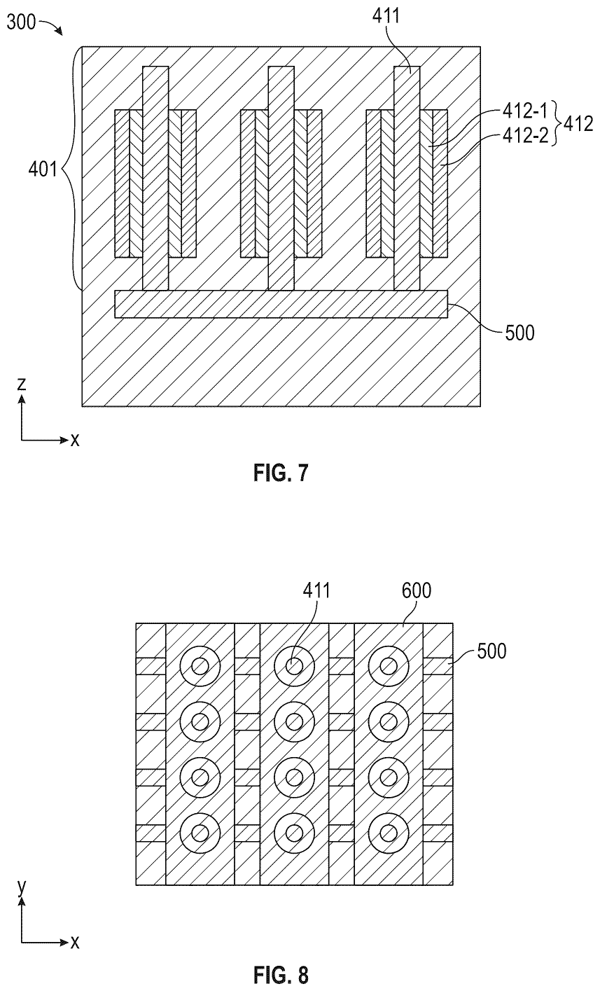

FIG. 3 is a partial sectional view of a second semiconductor structure 300 according to an implementation of the present application. FIG. 4 is a partial top view of a second semiconductor structure 300 according to an implementation of the present application. FIG. 5 is a partial sectional view of a second semiconductor structure 300 according to another implementation of the present application. FIG. 6 is a partial top view of a second semiconductor structure 300 according to another implementation of the present application. FIG. 7 is a partial sectional view of a second semiconductor structure 300 according to another implementation of the present application. FIG. 8 is a partial top view of a second semiconductor structure 300 according to another implementation of the present application.

For example, as shown in FIGS. 1-8, the memory cell 400 may include a transistor 401 and a storage cell 402 coupled to the transistor 401, wherein a plurality of memory cells 400 may form a memory cell array. Considering a DRAM (Dynamic Random Access Memory) as an example, a semiconductor device 1000 may include a memory cell 400 consisting of a capacitor (storage cell 402) and a transistor 401, wherein a plurality of memory cells 400 may be arranged in the form of a two-dimensional array.

In other words, in some implementations, the storage cell 402 may include a capacitor for storing charges as binary information stored by respective DRAM cell. Furthermore, in some implementations, the storage cell 402 may include a PCM (phase change memory) element (e.g., including a chalcogenide alloy) for storing binary information of respective PCM cells based on different resistivities of the PCM element in amorphous and crystal phases. In addition, in some implementations, the storage cell 402 may include a ferroelectric capacitor for storing binary information of respective FRAM (ferroelectric random access memory) cells based on the ferroelectric material that switches between two polarization states in external electrical field.

In some implementations, in order to further reduce the size of the two-dimensional array, the transistor 401 may include a vertical gate transistor (VGT). In such a structure, the source and drain of the transistor are located respectively on two ends in the extension direction of the channel of the transistor and the gate structure of the transistor is located on at least one side of the channel. For example, as shown in FIGS. 3-8, the transistor 401 may include a semiconductor body 411 extending in z direction and a gate structure 412 on at least one side wall of the semiconductor body 411.

In an implementation of the present application, a vertical transistor such as a vertical metal oxide semiconductor field effect transistor (MOSFET) may replace a relevant planar transistor as the pass transistor of the memory cell to reduce the area occupied by the pass transistor, the coupling capacitance and the complexity of interconnect wirings. In some implementations, unlike the planar transistor in which the active region is formed in substrate, a vertical transistor may include a semiconductor body 411 extending vertically in z direction over the substrate (not shown). The semiconductor body 411 may extend over the top surface of the substrate. Not only the top surface of the semiconductor body 411, but also one or more side walls of the semiconductor body 411 are exposed.

In an example, the semiconductor body 411 may have a cuboid shape to expose its four side walls. However, those skilled in the art should appreciate that the semiconductor body 411 may have any suitable 3D shape such as a polyhedron shape or a cylindrical shape. In other words, the cross section of the semiconductor body 411 in x-y plane may be of square shape, rectangular shape, trapezoid shape, circular shape, oval shape or any other suitable shapes. It should be understood that consistent with the scope of the present application, for the semiconductor body having circular or oval cross section in the above-described plane, the semiconductor body can still be considered as having a plurality of side walls such that the gate structure contacts one side wall of the semiconductor body. As described below with respect to the fabrication process, the semiconductor body 411 may be formed of the substrate by etching or epitaxy process for example and therefore can have the same semiconductor material as the substrate.

As an example, the substrate material may include, but is not limited to silicon (such as single crystalline silicon c-Si), silicon germanium (SiGe), gallium arsenide (GaAs), germanium (Ge), silicon on insulator (SOI) or any other suitable semiconductor material. For example, the substrate may be a silicon substrate. Accordingly, the semiconductor body 411 may include at least one of the above-described materials.

In some implementations, the transistor 401 may further include a source (not shown) and a drain (not shown) formed on two ends of the semiconductor body 411 in the z direction respectively, which may be understood as the doped regions of the semiconductor body 411 and may be called as source electrode and drain electrode. As an example, the source and drain may be doped with any suitable P-type dopant that may include any one of or combination of boron (B) or gallium (Ga). As another example, the source and drain may be doped with any suitable N-type dopant that may include any one of or combination of phosphorous (P), arsenic (As) and antimony (Sb). The source and drain may be separated in z direction by the gate structure 412. In other words, the gate structure 412 is formed between the source and drain in z direction. Therefore, when the gate voltage applied to the gate structure 412 is higher than the threshold voltage of the vertical transistor, the channel of the vertical transistor may be formed in the semiconductor body 411 in z direction between the source and drain (which may be considered as the gating capability of the gate structure).

In an example, as shown in FIG. 1, in the z direction, the transistor 401 is closer to the first semiconductor structure 200 than the storage cell 402 so as to facilitate shortening the length of the connecting wire between the transistor 401 and the first semiconductor structure 200 and reducing parasitic capacitance of the connecting wire.

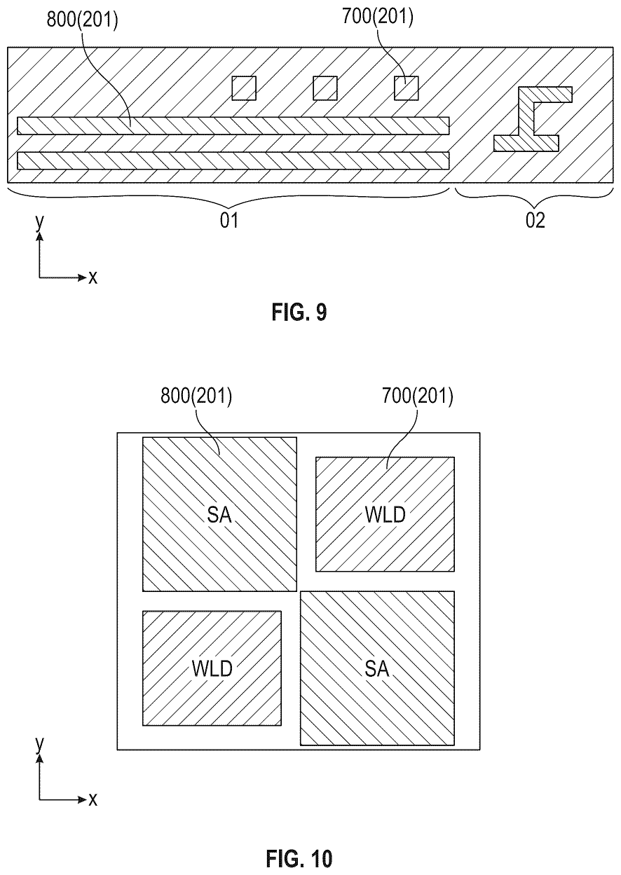

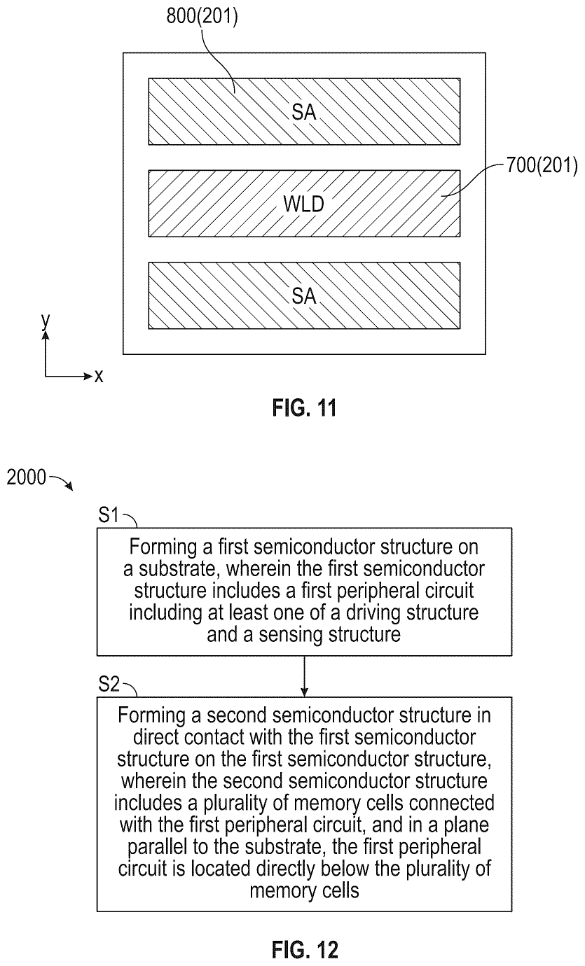

FIG. 9 is a top view of a first peripheral circuit 201 according to an implementation of the present application. FIG. 10 is a top view of a first peripheral circuit 201 according to another implementation of the present application. FIG. 11 is a top view of a first peripheral circuit 201 according to another implementation of the present application.

With reference to FIGS. 1, 2 and 9-11, in an example, one of the source and drain of the transistor 401 may be coupled with the storage cell 402. Furthermore, the second semiconductor structure 300 further includes a bit line 500 and a word line 600, wherein the bit line 500 may extend in x direction and be connected with the other of the source and drain of the transistor 401. The word line 600 may extend in y direction and be connected with the gate structure 412 of the transistor 401. It may be understood that the gate structure 412 and the word line 600 may be a continuous conductive structure. The gate structure 412 may be considered as an extension of the word line 600 for coupling the semiconductor body 411. Alternatively, the word line 600 may be considered as an extension of the gate structure 412 for coupling the peripheral circuit such as the first peripheral circuit 201. In some implementations, the second semiconductor structure 300 includes a plurality of bit lines and word lines.

In an example, as shown in FIGS. 1, 2 and 9, the semiconductor device 1000 may include a first region 01 and a second region 02, wherein the first peripheral circuit 201 is in the first region 01. The first peripheral circuit 201 includes at least one of a driving structure 700 and a sensing structure 800. Additionally, other parts of the peripheral circuit may be in the second region 02.

In an example, as shown in FIGS. 1, 2 and 10, in the plane parallel to x-y plane, a plurality of driving structures 700 are distributed symmetrically. Alternatively, a plurality of sensing structures 800 are distributed symmetrically. Alternatively, a plurality of driving structures 700 and a plurality of sensing structures 800 are both distributed symmetrically. For example, a plurality of driving structures 700 are distributed in a center symmetry. Alternatively, a plurality of sensing structures 800 are distributed in a center symmetry. Alternatively, a plurality of driving structures 700 and a plurality of sensing structures 800 are both distributed in a center symmetry. In an example, as shown in FIGS. 1, 2 and 11, in the plane parallel to x-y plane, the driving structures 700 and sensing structures 800 are arranged alternatively in x direction or y direction. It is appreciated that due to process error, the symmetrical distribution herein should be interpreted as roughly symmetrical distribution and structures with similar arrangement should also be considered as falling within the scope of the present application.

In other words, the bit line 500 and word line 600 may extend in two lateral directions perpendicular to each other and the semiconductor body 411 of the transistor 401 may extend in a vertical direction perpendicular to the two lateral directions in which the bit line 500 and word line 600 extend. Therefore, due to the vertical arrangement of the transistor 401, the word line 600 and bit line 500 may be arranged in different planes in the vertical direction, which simplifies the routing of word line 600 and bit line 500.

In addition, at least one of the sensing structure 800 connected with the bit line 500 and the driving structure 700 connected with the word line 600 is disposed directly below the plurality of memory cells 400. In other words, in the plane perpendicular to z direction, the projection of the plurality of memory cells 400 partially overlaps with the projection of at least one of the sensing structure 800 and the driving structure 700, which facilitates shortening the length of the connecting wires between the first peripheral circuit 201 and the plurality of memory cells 400, thereby in turn reducing the parasitic capacitance of the connecting wires and improving the sensing tolerance and storage density of the semiconductor device 1000.

Furthermore, with reference to FIGS. 1 and 2, the semiconductor device 1000 further includes a bit line contact structure 58 connecting the bit line 500 and the sensing structure 800 and a word line driving structure 67 connecting the word line 600 and the driving structure 700. In order to strengthen the above effect, at least one of the bit line contact structure 58 and the word line driving structure 67 may extend in z direction to enhance the effect of shortening the length of the connecting wire, thereby in turn reducing the parasitic capacitance of the connecting wire and improving the sensing tolerance and storage density of the semiconductor device 1000.

It is appreciated that the sensing structure 800 mentioned above includes a bit line sensing amplifying structure connected with the bit line 500 and the driving structure 700 includes a word line driving structure connected with the word line 600.

Furthermore, according to some implementations, both the word line 600 and bit line 500 may include conductive materials including, but not limited to tungsten (W), cobalt (Co), copper (Cu), aluminum (Al), titanium nitride (TiN), tantalum nitride (TaN), polysilicon, silicide or any combination thereof. In some implementations, the word line 600 and bit line 500 may include a plurality of conductive layers such as W layers over the TiN layer.

Furthermore, in some implementations of the present application, the first semiconductor structure 200 further includes a first interconnect structure 910, wherein the first interconnect structure 910 is located on a side of the first peripheral circuit 201 close to the second semiconductor structure 300 in z direction so as to connect the first semiconductor structure 200 and the second semiconductor structure 300.

Furthermore, the semiconductor device 1000 further includes a power layer 930 for providing electrical signals to the peripheral circuit. In some implementations of the present application, the power layer 930 is located in the second semiconductor structure 300 and connected with the peripheral circuit of the first semiconductor structure 200 via the second interconnect structure 920 of the second semiconductor structure 300.

Furthermore, the power layer 930 may be located on a side of the plurality of memory cells 400 away from the first semiconductor structure 200 in z direction. Based on this, the second interconnect structure 920 may extend in z direction to connect the power layer 930 and the peripheral circuit of the first semiconductor structure 200.

In related technologies, the power layer for providing electrical signals to peripheral circuit is typically disposed close to the peripheral circuit. Furthermore, the first interconnect structure for connecting the peripheral circuit and the plurality of memory cells and the second interconnect structure for connecting the power layer and the peripheral circuit are typically disposed together. However, such a layout restricts where connecting wires can be provided and reduces the flexibility of layout.

As described above, the interconnect structure (which may be understood as the connecting wire above) includes the first interconnect structure for connecting the first semiconductor structure and the second semiconductor structure and the second interconnect structure for connecting the power layer and the first semiconductor structure. In some implementations of the present application, disposing the first interconnect structure and the second interconnect structure separately may increase spatial locations for the interconnect structure layout and enhance the flexibility of interconnect structure layout. Based on this, in order to enhance the above-described effect, the power layer for providing electrical signals to the peripheral circuit of the first semiconductor structure may also be disposed on a side of the plurality of memory cells away from the first semiconductor structure in z direction.

In addition, the semiconductor device 1000 further includes a first pad 940 connecting external electrical signals, which may be connected with the power layer 930 or the peripheral circuit in the first semiconductor structure 200. In an example, the first pad 940 may be disposed in the second semiconductor structure 300 to increase spatial locations for the interconnect structure layout in the semiconductor device 1000 and improve flexibility of the interconnect structure layout.

Furthermore, referring again to FIGS. 3-8, in some implementations of the present application, the transistor 401 may include at least one of a gate all around transistor, a multi-gate transistor and a single gate transistor.

For example, as shown in FIGS. 3 and 4, in some implementations of the present application, the transistor 401 may include a single gate transistor. In this case, the semiconductor body 411 includes a first section A and a second section B connected with each other, wherein the first section A extends in z direction and the first section B extends in x direction perpendicular to z direction. In an example, the semiconductor body 411 has a “L” shaped cross section in x-z plane. A plurality of semiconductor bodies 411 may be arrange in an array. The conductive portion of the gate structure 412 (which may be understood as the gate conductive layer below) is located on the side wall of the first section A of the semiconductor body 411 in x direction.

Furthermore, in an example, a plurality of semiconductor bodies 411 close to each other in x direction are distributed in mirror symmetry in z direction. In an example, a plurality of gate structures 412 close to each other in x direction are similarly distributed in mirror symmetry in z direction. Accordingly, in at least one implementation of the present application, the semiconductor device includes single gate transistors (also referred to as single-side gate transistors) adjacent to each other and arranged in mirror symmetry in the bit line direction, which may drastically increase the memory cell density in the bit line direction while not complicating the manufacturing process. Furthermore, as compared to relevant planar transistors, multi-gate vertical transistors (such as having two-side gates) or gate all around vertical transistors, single gate transistors in mirror symmetry have a larger process window for reducing pitches of the word lines, bit lines and transistors.

Furthermore, as shown in FIGS. 5-8, in some implementations of the present application, the transistor 401 may include a multi-gate transistor. In this case, the transistor 401 may include a gate structure 412 in contact with one or more side walls of the semiconductor body 411. For example, the gate structure 412 may be located on two side walls opposite to each other in x direction of the semiconductor body 411 (also referred to as a two-side gate transistor). Furthermore, based on this, the gate structure 412 may also be located on side walls other than the two side walls opposite in x direction of the semiconductor body 411 (which may also be referred to as gate all around transistor), which is not limited in the present application.

In other words, the gate structure 412 may contact more than one side walls of the semiconductor body 411 to form more than one gate structures such that more than one channels may be formed between the source and drain in operation. For example, the gate structure 412 may be located on one of the two opposite sides in x direction of the semiconductor body 411 and based on this, further located on side walls other than the two opposite ones in x direction of the semiconductor body 411.

Unlike the planar transistor that includes only one planar gate, due to the three dimensional (3D) structure of the semiconductor body 411 and the gate structure 412 surrounding a plurality of side walls of the semiconductor body 411, the multi-gate vertical transistor has a larger gate control area than the planar transistor so as to better control the channels with a smaller sub-threshold swing. Furthermore, for the purpose of, e.g., increasing the densities of transistors and memory cells, the gate structure 412 may also only contact a single side wall of the semiconductor body 411, for example, one of the two opposite side walls in x direction of the semiconductor body 411, which is not limited herein.

For example, as shown in FIGS. 5-6, in case that the transistor 401 is a dual side gate transistor, the semiconductor body 411 may include a first section A and a second section B connected with each other. The first section A extends in z direction and the second section B extends in x direction perpendicular to z direction. In an example, the semiconductor body 411 has an inverted “T” shaped cross section in x-z plane. The conductive portion of the gate structure 412 (which may be understood as the gate conductive layer below) is located symmetrically on the side wall of the first section of the semiconductor body 411 in x direction.

As shown in FIGS. 7-8, in case that the transistor 401 is a gate all around transistor, the semiconductor body 411 may include a number of side walls and the conductive portion of the gate structure 412 (which may be considered as the gate conductive layer below) surrounds all side walls of the semiconductor body 411.

Furthermore, referring again to FIGS. 3-8, in an implementation of the present application, the gate structure 412 may include a gate dielectric layer 412-1 over one or more side walls of the semiconductor body 411. Furthermore, the gate structure 412 may further include a gate conductive layer 412-2 over and in contact with the gate dielectric layer 412-1. The gate conductive layer 412-2 may include a gate adhesive layer (not shown) and a gate metal layer (not shown) over and in contact with the gate adhesive layer. In other words, the gate adhesive layer is located between the gate dielectric layer 412-1 and the gate metal layer.

The gate dielectric layer 412-1 may include any suitable dielectric material such as silicon oxide, silicon nitride, silicon oxynitride or high-k dielectric. For example, the gate dielectric layer 412-1 may include silicon oxide. Furthermore, the gate adhesive layer may include, but is not limited to titanium, titanium nitride, tantalum, tantalum nitride, etc. In addition, the gate metal layer may include any suitable conductive material. For example, the gate metal layer may include, but is not limited to tungsten (W), cobalt (Co), copper (Cu), aluminum (Al), etc. The gate adhesive layer is configured to block the diffusion of metal material in the gate metal layer and also to enhance the adhesion between the gate metal layer and the gate dielectric layer 412-1.

In addition, referring again to FIGS. 1 and 2, in some implementations of the present application, the transistor 401 may include a thin film transistor. In other words, a plurality of memory cells 400 including thin film transistors may be formed on the first semiconductor structure 200 by film fabrication process.

For example, a thin film transistor includes a semiconductor body 411 that may be an oxide semiconductor layer containing at least one of indium, gallium or zinc. For example, due to its relatively high carrier mobility and relatively low leakage current, the semiconductor body 411 formed of low temperature material IGZO (Indium Gallium Zinc Oxide) may further save the use of semiconductor material, reduce the fabrication cost and reduce the overall size of the semiconductor device.

Furthermore, the thin film transistor further includes a source electrode layer and a drain electrode layer. As an example, a buffer layer may be disposed between the source and drain electrode layers and the oxide semiconductor layer, wherein the buffer layer has a higher carrier concentration than the oxide semiconductor layer to form an ohmic contact. In an example, the buffer layer may contain N-type or P-type conducting dopant elements.

Therefore, as described above, according to at least one implementation of the present application, the semiconductor device includes a first semiconductor structure and a second semiconductor structure over and in direct contact with the first semiconductor structure, wherein the second semiconductor structure includes a plurality of memory cells, the first semiconductor structure includes a first peripheral circuit connected with the plurality of memory cells, and at least a portion of the first peripheral circuit is located directly below the plurality of memory cells. In other words, the second semiconductor structure including the plurality of memory cells is formed on a peripheral circuit wafer and a portion of the peripheral circuit may be located directly below the plurality of memory cells. Therefore, it is possible to reduce the fabrication cost of the semiconductor device, decrease the overall size of the semiconductor device and improve the storage density of the semiconductor device without impacting the comprehensive performance of the semiconductor device.

In addition, referring again to FIGS. 1-6, some implementations of the present application provide a semiconductor device 1000. For example, the semiconductor device 1000 includes a first semiconductor structure 200 and a semiconductor body 411. The semiconductor body 411 is disposed on a side of the first semiconductor structure 200 in z direction and includes a first section A and a second section B connected with each other. The first section A extends in z direction and the second section B extends in a direction perpendicular to z direction and directly contacts the first semiconductor structure 200.

Therefore, with the semiconductor device provided according to at least one implementation of the present application, the semiconductor device includes a first semiconductor structure and plurality of memory cells over and in direct contact with the first semiconductor structure in z direction. For example, the plurality of memory cells may each include a semiconductor pillar including a first section and a second section connected with each other, wherein the second section may extend in a direction perpendicular to z direction and directly contact the first semiconductor device. With the above-described configuration, it is possible to form the plurality of memory cells on the peripheral circuit wafer, reduce the fabrication cost of the semiconductor device, decrease the overall size of the semiconductor device and improve the storage density of the semiconductor device without impacting the comprehensive performance of the semiconductor device.

For example, in order to enhance the above effect, in an implementation of the present application, the first semiconductor structure 200 may include a first peripheral circuit 201 that may include at least one of a driving structure 700 and a sensing structure 800 connected with the plurality of memory cells, wherein at least a portion of the first peripheral circuit 201 may be located directly below the plurality of semiconductor bodies 411.

Furthermore, the semiconductor device 1000 further includes a power layer 930 for providing electrical signals to the peripheral circuit. In some implementations of the present application, a power layer 930 is located on a side of the semiconductor body 411 away from the first semiconductor structure 200 in z direction. The second interconnect structure 920 of the semiconductor device 1000 connects the peripheral circuit of the first semiconductor structure 200 and the power layer 930.

Furthermore, the semiconductor device 1000 further includes a first interconnect structure 910, wherein the first interconnect structure 910 is located on a side of the first peripheral circuit 201 close to the semiconductor body 411 in z direction so as to connect the first semiconductor structure 200 and the semiconductor body 411.

The interconnect structure of the semiconductor device includes the above-described first interconnect structure and second interconnect structure, and disposing the first interconnect structure and the second interconnect structure separately may increase spatial locations for the interconnect structure layout and enhance the flexibility of interconnect structure layout. Based on this, in order to enhance the above-described effect, the power layer for providing electrical signals to the peripheral circuit of the first semiconductor structure may also be disposed on a side of the plurality of memory cells away from the first semiconductor structure in z direction.

Furthermore, in an implementation of the present application, the semiconductor body 411 includes an oxide semiconductor layer. In other words, a plurality of semiconductor bodies 411 may be formed on the first semiconductor structure 200 by film manufacturing process. For example, due to its relatively high carrier mobility and relatively low leakage current, the semiconductor body 411 formed of low temperature material IGZO (Indium Gallium Zinc Oxide) may further save the use of semiconductor material, reduce the fabrication cost and reduce the overall size of the semiconductor device.

Furthermore, in an implementation of the present application, the semiconductor structure 1000 further includes a gate structure 412. The gate structure 412 is located at the first section A and the second section B. In an example, the gate structure 412 includes a gate dielectric layer 412-1 and a gate conductive layer 412-2 over and in contact with the gate dielectric layer 412-1. The gate conductive layer 412-2 extends on the first section A in z direction and includes two ends opposite in z direction, in which one end is on the second section B.

Furthermore, in an implementation of the present application, the semiconductor structure 1000 further includes a bit line 500 and a word line 600. The bit line 500 may extend in x direction, and may be located on a side of the second section B away from the first section A or on a side of the first section A away from the second section B. The word line 600 may extend in y direction and be connected with the gate structure 412 of the transistor 401. It may be understood that the gate structure 412 and the word line 600 may be a continuous conductive structure. The gate structure 412 may be considered as an extension of the word line 600 for coupling the semiconductor body 411. Alternatively, the word line 600 may be considered as an extension of the gate structure 412 for coupling the peripheral circuit such as the first peripheral circuit 201.

In an example, as shown in FIGS. 3 and 4, a plurality of semiconductor bodies 411 close to each other in x direction are distributed in mirror symmetry in z direction. In an example, a plurality of gate structures 412 close to each other in x direction are similarly distributed in mirror symmetry in z direction. Accordingly, in at least one implementation of the present application, the semiconductor device includes single gate transistors (also referred to as single side gate transistors) adjacent to each other and arranged in mirror symmetry in the bit line direction, which may drastically increase the memory cell density in the bit line direction while not complicating the manufacturing process. Furthermore, as compared to relevant planar transistors or multi-gate vertical transistors (such as having two-side or all-around gates), single gate transistors in mirror symmetry have a larger process window for reducing pitches of the word lines, bit lines and transistors.

In addition, as shown in FIGS. 1, 2 and 9-11, in an implementation of the present application, the first peripheral circuit 201 includes a driving structure 700 connected with the word line 600 and a sensing structure 800 connected with the bit line 500. In an example, in the plane parallel to x-y plane, a plurality of driving structures 700 are distributed in a center symmetry. Alternatively, a plurality of sensing structures 800 are distributed in a center symmetry. Alternatively, a plurality of driving structures 700 and a plurality of sensing structures 800 are both distributed in a center symmetry. In an example, in the plane parallel to x-y plane, the driving structures 700 and sensing structures 800 are arranged alternately in x direction or y direction.

In other words, the bit line 500 and word line 600 may extend in two lateral directions perpendicular to each other and the semiconductor body 411 of the transistor 401 may extend in a vertical direction perpendicular to the two lateral directions in which the bit line 500 and word line 600 extend. Therefore, due to the vertical arrangement of the transistor 401, the word line 600 and bit line 500 may be arranged in different planes in the vertical direction, which simplifies the routing of word line 600 and bit line 500.

In addition, at least one of the sensing structure 800 connected with the bit line 500 and the driving structure 700 connected with the word line 600 is disposed directly below the plurality of memory cells 400, which facilitates shortening the length of the connecting wires between the first peripheral circuit 201 and the plurality of memory cells 400, thereby in turn reducing the parasitic capacitance of the connecting wires and improving the sensing tolerance and storage density of the semiconductor device 1000.

Furthermore, with reference to FIGS. 1 and 2, the semiconductor device 1000 further includes a bit line contact structure 58 connecting the bit line 500 and the sensing structure 800 and a word line driving structure 67 connecting the word line 600 and the driving structure 700. In order to strengthen the above effect, at least one of the bit line contact structure 58 and the word line driving structure 67 may extend in z direction to enhance the effect of shortening the length of the connecting wires, thereby in turn reducing the parasitic capacitance of the connecting wires and improving the sensing tolerance and storage density of the semiconductor device 1000.

It is appreciated that the sensing structure 800 mentioned above includes a bit line sensing amplifying structure connected with the bit line 500 and the driving structure 700 includes a word line driving structure connected with the word line 600.

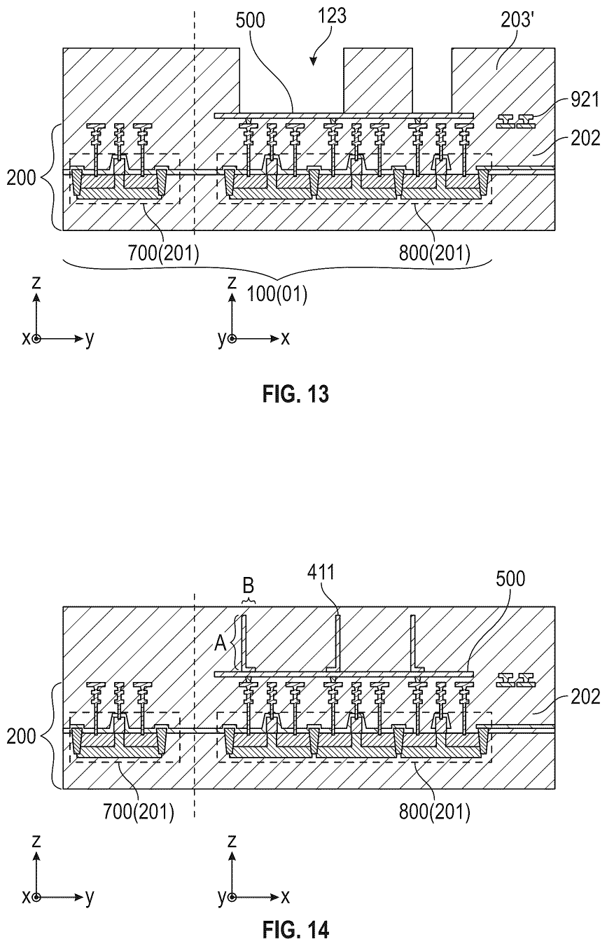

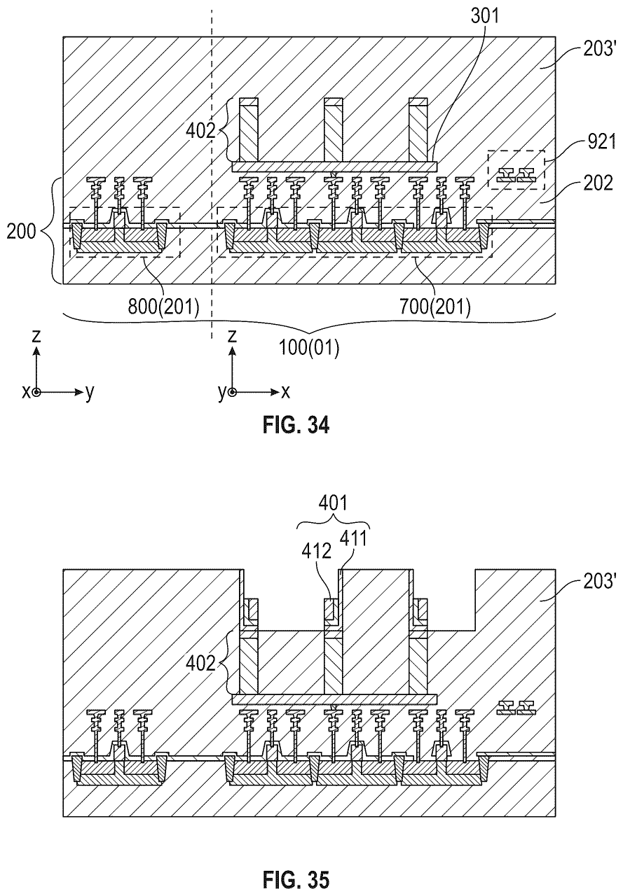

Some implementations of the present application provide a fabrication method of a semiconductor device. FIG. 12 is a flow chart of a method 2000 of fabricating a semiconductor device according to an example implementation of the present application. FIGS. 13-33 are process diagrams of a fabrication method 2000 of a semiconductor device according to an implementation of the present application respectively; and FIGS. 34-38 are process diagrams of a fabrication method 2000 of a semiconductor device according to another implementation of the present application respectively.

As shown in FIG. 12, the present application provides a fabrication method 2000 of a semiconductor device, including:
S1, forming a first semiconductor structure on a substrate, wherein the first semiconductor structure includes a first peripheral circuit including at least one of a driving structure and a sensing structure; and
S2, forming a second semiconductor structure in direct contact with the first semiconductor structure on the first semiconductor structure, wherein the second semiconductor structure includes a plurality of memory cells connected with the first peripheral circuit, and in a plane parallel to the substrate, the first peripheral circuit is located directly below the plurality of memory cells.

Processes of operations of the above-described fabrication method 2000 in implementation I will be described in detail below in connection with FIGS. 13-33.

### Implementation I

### Operation S1

FIG. 13 is a sectional view of the resultant structure after forming the first semiconductor structure 200 in the fabrication method according to an implementation of the present application.

As shown in FIGS. 12-13, the operation S1 of forming a first semiconductor structure on a substrate, wherein the first semiconductor structure includes a first peripheral circuit including at least one of a driving structure and a sensing structure, may include for example: providing a substrate 100; and forming a first peripheral circuit 201 in the substrate 100.

For example, in an implementation of the present application, the material for fabricating the substrate 100 may be selected as any suitable semiconductor material such as single crystalline silicon (Si), single crystalline germanium (Ge), silicon germanium (GeSi), silicon carbide (SiC), silicon-on-insulator (SOI), germanium-on-insulator (GOI), or III-V compounds such as gallium arsenide. As an example, the substrate 100 may be selected as single crystalline silicon.

In an implementation of the present application, the substrate 100 may be such as a composite substrate to provide support for device structures thereon. A plurality of layers of different materials may be disposed successively with a thin film deposition process such as chemical vapor deposition (CVD), physical vapor deposition (PVD), atomic layer deposition (ALD) or any combination thereof to form the substrate 100.

In an implementation of the present application, the substrate 100 may include a substrate sacrificial layer (not shown). In an example, the substrate sacrificial layer may include a single layer, a plurality of layers or a suitable composite layer. For example, the substrate sacrificial layer may include any one or more of a silicon oxide layer, a silicon nitride layer and a silicon oxynitride layer. As an example, the substrate sacrificial layer may be a high dielectric constant dielectric layer. As another example, the substrate sacrificial layer may include a dielectric layer, a sacrificial layer and a dielectric layer disposed successively, wherein the dielectric layers may be silicon nitride layers and the sacrificial layer may be a silicon oxide layer. As yet another example, the substrate sacrificial layer may include any one or more of dielectric material, semiconductor material and conductive material. For example, the sacrificial layer may be single crystalline silicon or polycrystalline silicon. For example, in an implementation of the present application, an example material for forming the sacrificial layer is polysilicon.

Furthermore, partial regions of the substrate 100 may be further formed with doped well regions (not shown) by ion implanting or diffusing N type or P type dopants. The dopant may include any one or a combination of phosphorous (P), arsenic (As) and antimony (Sb); or any one or a combination of boron (B), gallium (Ga) or indium (In). In some implementations of the present application, the well regions may be fabricated with the same dopant or different dopants. Further, the doping concentrations of well regions may be the same or different, which is not limited in the present application.

After forming the substrate 100, a peripheral circuit may be formed in the substrate, wherein the peripheral circuit includes a first peripheral circuit 201 including at least one of a driving structure 700 and a sensing structure 800.

In an example, the driving structure 700 includes a word line driving structure connected with the word line in the subsequently formed second semiconductor structure. The sensing structure 800 includes a bit line sensing amplifying structure connected with the bit line in the subsequently formed second semiconductor structure. The driving structure 700, the sensing structure 800 and other peripheral circuits may be fabricated with relevant processes and according to practical requirements, which will not be described any longer.

In an example, at least a portion of the first peripheral circuit 201 is formed in the first region 01 of the substrate 100, and the plurality of memory cells in the subsequently formed second semiconductor structure are formed over the first region 01.

It is to be noted that in FIGS. 13-33 herein, only the numbers and locations of memory cells and peripheral circuit are illustrated. It is appreciated that the memory cells and peripheral circuit shown in the figures and related contents herein are only for the purpose of convenient illustration and the present application is not limited thereto. Those skilled in the art can modify the memory cells and peripheral circuit according to the concept of the present disclosure to achieve the same technical effect. Furthermore, in FIG. 13 and other figures in implementation I herein, for convenience of observation, the cross section of the intermediate of the semiconductor device 1000 that is parallel to x-z plane and the cross section that is parallel to y-z plane are disposed on two sides of the dashed-dotted line respectively.

In an example, referring to FIGS. 1, 10 and 11, in the plane parallel to the substrate 100 (x-y plane), the driving structures 700 and sensing structures 800 may be arranged alternatively in x direction or y direction. In an example, in the x-y plane, at least one of: a plurality of driving structures 700 may be distributed in a center symmetry, or a plurality of sensing structures 800 may be distributed in a center symmetry.

Furthermore, in an implementation of the present application, the operation S1 of forming a first semiconductor structure on a substrate, wherein the first semiconductor structure includes a first peripheral circuit including at least one of a driving structure and a sensing structure, further includes forming an interconnect contact 921 connected with the second interconnect structure that is configured to connect the first semiconductor structure 200 and the subsequently formed power layer. The interconnect contact 921 may adopt relevant structure and may be fabricated with relevant processes and according to practical requirements, which will not be described any longer.

In addition, in an implementation of the present application, after forming the first peripheral circuit 201, operation S1 of forming a first semiconductor structure on a substrate, wherein the first semiconductor structure includes a first peripheral circuit including at least one of a driving structure and a sensing structure, further includes: forming a first dielectric separating layer 202 covering at least the first peripheral circuit 201 with one or more thin film deposition processes which may include, but are not limited to chemical vapor deposition (CVD), physical vapor deposition (PVD), atomic layer deposition (ALD) or any combinations thereof. In an example, the first dielectric separating layer 202 may include any suitable dielectric material such as oxide, nitride, oxynitride or high-k dielectric. For example, the first dielectric separating layer 202 may include silicon oxide. Furthermore, there is no distinct boundary between the first dielectric separating layer 202 and the subsequently formed initial second dielectric separating layer 203′ in case that they are fabricated with the same material.

### Operation S2

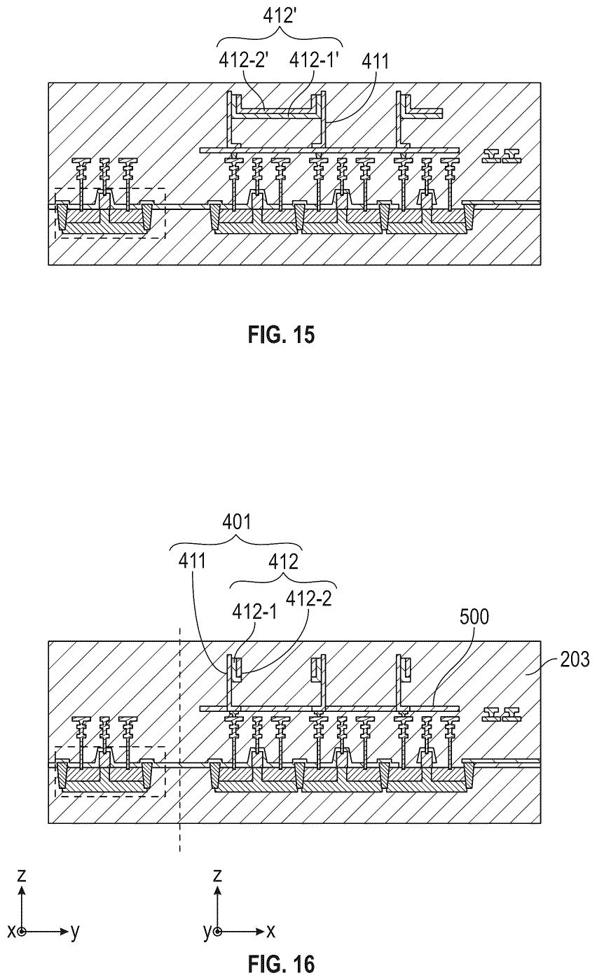

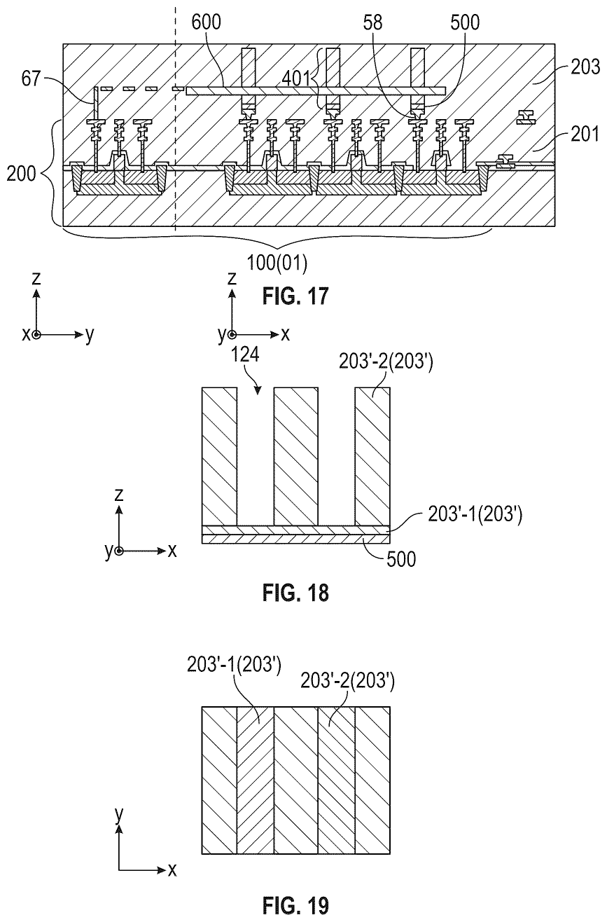

FIG. 14 is a sectional diagram of the resultant structure after forming semiconductor body 411 in the fabrication method according to an implementation of the present application. FIG. 15 is a sectional diagram of the resultant structure after forming the initial gate structure 412′ in the fabrication method according to an implementation of the present application. FIG. 16 is a sectional diagram of the resultant structure after forming the gate structure 412 in the fabrication method according to an implementation of the present application. FIG. 17 is a sectional diagram of the resultant structure after rotating the intermediate shown in FIG. 16 by 90° in x-y plane.

As shown in FIGS. 13-17, the operation S2 of forming a second semiconductor structure in direct contact with the first semiconductor structure on the first semiconductor structure, wherein the second semiconductor structure includes a plurality of memory cells connected with the first peripheral circuit, and in a plane parallel to the substrate, the first peripheral circuit is located directly below the plurality of memory cells, may include for example: forming a bit line 500 on the first semiconductor structure 200; forming a semiconductor body 411 and a gate structure 412 connected with the semiconductor body 411 on the bit line 500, wherein the semiconductor body 411 extends in the first direction (z direction) perpendicular to the substrate 100; and forming storage cells 402 connected with the semiconductor body 411 on the semiconductor body 411.

For example, as shown in FIG. 13, in an implementation of the present application, the bit line 500 is formed on the first peripheral circuit 201 with one or more thin film deposition processes which may include, but are not limited to chemical vapor deposition (CVD), physical vapor deposition (PVD), atomic layer deposition (ALD) or any combinations thereof.

The bit line 500 may extend in x direction perpendicular to z direction. In an example, the bit line 500 may include conductive materials including, but not limited to tungsten (W), cobalt (Co), copper (Cu), aluminum (Al), titanium nitride (TiN), tantalum nitride (TaN), polysilicon, silicide or any combination thereof. In some implementations, the bit line 500 may include a plurality of conductive layers such as W layers over the TiN layer.

After forming the bit line 500, the initial second dielectric separating layer 203′ covering the first semiconductor structure 200 and the bit line 500 may be formed with one or more thin film deposition processes which may include, but are not limited to chemical vapor deposition (CVD), physical vapor deposition (PVD), atomic layer deposition (ALD) or any combinations thereof.

In an example, the initial second dielectric separating layer 203′ may include any suitable dielectric material such as oxide, nitride, oxynitride or high-k dielectric. For example, the initial second dielectric separating layer 203′ may include silicon oxide. Furthermore, there is no distinct boundary between the initial second dielectric separating layer 203′ and the first dielectric separating layer 202 in case that they are fabricated with the same material.

As shown in FIGS. 13 and 14, in an implementation of the present application, forming the semiconductor body 411 extending in z direction on the bit line 500 may include for example: forming a first opening 123, wherein the first opening 123 extends to the bit line 500 in the initial second dielectric separating layer 203′ in z direction; forming an initial semiconductor body (not shown) on inner wall of the first opening 123; and removing partial initial semiconductor body to form the semiconductor body 411.

In an example, the first opening 123 extending in z direction is formed in the initial second dielectric separating layer 203′ with for example dry etching process or a combination of dry etching process and wet etching process, or by implementing other manufacturing processes such as patterning processes including photolithography, cleaning and chemical mechanical polishing. The number and locations of the first openings 123 are determined by the locations and number of the subsequently formed semiconductor bodies. For example, two semiconductor bodies 411 in mirror symmetry in x direction may be formed in the first opening 123. Furthermore, the radial size of the first opening 123 at the edge may be smaller than the radial size of the first opening 123 in the middle because only one semiconductor body 411 may be formed in the first opening 123 at the edge.

After forming the first opening 123, an initial semiconductor body may be formed on inner wall of the first opening 123 with one or more thin film deposition processes which may include, but are not limited to chemical vapor deposition (CVD), physical vapor deposition (PVD), atomic layer deposition (ALD) or any combinations thereof.

As an example, the initial semiconductor body may be formed with thin film fabrication processes. For example, the initial semiconductor body may be an oxide semiconductor layer containing at least one of indium, gallium or zinc.

In an example, the initial semiconductor body is formed with low temperature deposition process. The process temperature T for low temperature deposition may satisfy: 200° C.≤T≤300° C. For example, due to its relatively high carrier mobility and relatively low leakage current, the initial semiconductor body formed of low temperature material IGZO may further save the use of semiconductor material, reduce the fabrication cost and reduce the overall size of the semiconductor device.

After forming the initial semiconductor body, the semiconductor body 411 is formed with for example dry etching process or a combination of dry etching process and wet etching process, or by implementing other manufacturing processes such as patterning processes including photolithography, cleaning and chemical mechanical polishing to remove partial initial semiconductor body.

Furthermore, a source (not shown) and a drain (not shown) may also be formed by a doping process on two opposite ends of the semiconductor body 411 in the z direction, which may be understood as the doped regions of the semiconductor body 411 and may also be called as source electrode and drain electrode. As an example, the source and drain may be doped with any suitable P-type dopant that may include any one of or combination of boron (B) or gallium (Ga). As another example, the source and drain may be doped with any suitable N-type dopant that may include any one of or combination of phosphorous (P), arsenic (As) and antimony (Sb).

As shown in FIG. 14, the semiconductor body 411 includes a first section A and a second section B connected with each other, wherein the first section A extends in z direction and the second section B extends in x direction perpendicular to z direction. In an example, the semiconductor body 411 has a “L” shaped cross section in x-z plane. A plurality of semiconductor bodies 411 may be arranged in an array.

In addition, as shown in FIGS. 13-14, in an implementation of the present application, after forming the semiconductor body 411, a dielectric material layer may be filled in the first opening 123 in which the semiconductor body 411 has been formed with one or more thin film deposition processes which may include, but are not limited to chemical vapor deposition (CVD), physical vapor deposition (PVD), atomic layer deposition (ALD) or any combinations thereof.

Furthermore, it is also possible to implement any suitable planarization process such as at least one of grinding or chemical mechanical polishing process to treat the upper surfaces of the filled dielectric material layer and the initial second dielectric separating layer 203′ such that the treated filled dielectric material layer and the initial second dielectric separating layer 203′ have relatively flat upper surfaces, thereby facilitating performing of subsequent processes on the flat surfaces.

As shown in FIGS. 14-16, in an implementation of the present application, forming the gate structure 412 connected with the semiconductor body 411 may include for example: forming a second opening (not shown) extending in z direction in the filled dielectric material layer; forming an initial gate structure 412′ on inner wall of the second opening; and removing partial initial gate structure 412′ to form the gate structure 412.

In an example, the second opening extending in z direction is formed in the filled dielectric material layer with for example dry etching process or a combination of dry etching process and wet etching process, or by implementing other manufacturing processes such as patterning processes including photolithography, cleaning and chemical mechanical polishing. The number and locations of the second openings are determined by the locations and number of the subsequently formed gate structures. For example, two gate structures 412 in mirror symmetry in x direction may be formed in the second opening. Furthermore, the radial size of the second opening at the edge may be smaller than the radial size of the second opening in the middle because only one gate structure 412 may be formed in the second opening at the edge.

After forming the second opening, an initial gate structure 412′ may be formed on inner wall of the second opening with one or more thin film deposition processes which may include, but are not limited to chemical vapor deposition (CVD), physical vapor deposition (PVD), atomic layer deposition (ALD) or any combinations thereof.

In an example, the initial gate structure 412′ includes an initial gate dielectric layer 412-1′ and an initial gate conductive layer 412-2′ over and in contact with the initial gate dielectric layer 412-1′. In addition, the initial gate conductive layer 412-2′ may include an initial gate adhesive layer (not shown) and an initial gate metal layer (not shown) over and in contact with the initial gate adhesive layer. In other words, the initial gate adhesive layer is located between the initial gate dielectric layer 412-1′ and the initial gate metal layer.

The initial gate dielectric layer 412-1′ may include any suitable dielectric material such as silicon oxide, silicon nitride, silicon oxynitride or high-k dielectric. For example, the initial gate dielectric layer 412-1′ may include silicon oxide. Furthermore, the initial gate adhesive layer may include, but is not limited to titanium, titanium nitride, tantalum, tantalum nitride etc. In addition, the initial gate metal layer may include any suitable conductive material. For example, the initial gate metal layer may include, but is not limited to tungsten (W), cobalt (Co), copper (Cu), aluminum (Al) etc. The initial gate adhesive layer is configured to block the diffusion of metal material in the initial gate metal layer and also to enhance the adhesion between the initial gate metal layer and the initial gate dielectric layer 412-1′.

After forming the initial gate structure 412′, the gate structure 412 may be formed with for example dry etching process or a combination of dry etching process and wet etching process, or by implementing other manufacturing processes such as patterning processes including photolithography, cleaning and chemical mechanical polishing to remove partial initial gate structure 412′.

As shown in FIGS. 16 and 17, after forming the gate structure 412, it is understood that the transistor 401 has been formed. In the transistor 401, the conductive portion of the gate structure 412 (which may be understood as the gate conductive layer above) is located on the side wall of the first section A of the semiconductor body 411 in x direction.

In other words, a plurality of semiconductor bodies 411 close to each other in x direction are distributed in mirror symmetry in z direction and further, a plurality of gate structures 412 close to each other in x direction are similarly distributed in mirror symmetry in z direction. Accordingly, in at least one implementation of the present application, the semiconductor device includes single gate transistors (also referred to as single-side gate transistors) adjacent to each other and arranged in mirror symmetry in the bit line direction, which may drastically increase the memory cell density in the bit line direction while not complicating the manufacturing process. Furthermore, as compared to relevant planar transistors or multi-gate vertical transistors (such as having two-side gates) or gate all around vertical transistors, single gate transistors in mirror symmetry have a larger process window for reducing pitches of the word lines, bit lines and transistors.

In an example, a word line 600 connecting the gate structures 412 may be formed with one or more thin film deposition processes which may include, but are not limited to chemical vapor deposition (CVD), physical vapor deposition (PVD), atomic layer deposition (ALD) or any combinations thereof.

The word line 600 may extend in y direction perpendicular to z direction. In an example, the word line 600 may include conductive materials including, but not limited to tungsten (W), cobalt (Co), copper (Cu), aluminum (Al), titanium nitride (TiN), tantalum nitride (TaN), polysilicon, silicide or any combination thereof. In some implementations, the word line 600 may include a plurality of conductive layers such as W layers over the TiN layer.

Furthermore, in connection with FIGS. 1 and 17, after forming the transistor 401, the storage cells 402 connected with the semiconductor body 411 may also be formed on the semiconductor body 411. The storage cells 402 may adopt relevant structure and may be fabricated with relevant processes and according to practical requirements, which will not be described any longer in the present application.

In an example, in some implementations, considering a DRAM as an example, a storage cell 402 may include a capacitor and a plurality of storage cells 402 may be arranged in form of a two-dimensional array. In an example, in some implementations, considering a PCM element as an example, the storage cell 402 may include respective PCM unit with different resistivities in amorphous and crystalline phases for storing. For example, it includes a chalcogenide alloy. In an example, in some implementations, considering a FRAM as an example, a storage cell 402 may include a ferroelectric capacitor. This is not limited in the present application.

Furthermore, as shown in FIGS. 16 and 17, after forming the gate structure 412, spaces between a plurality of gate structures 412 or spaces remained in the second openings after forming the gate structures 412 may be filled with gate structure separating filling dielectric layers with one or more thin film deposition processes which may include, but are not limited to chemical vapor deposition (CVD), physical vapor deposition (PVD), atomic layer deposition (ALD) or any combinations thereof.

In an example, the gate structure separating filling dielectric layer may include any suitable dielectric material such as oxide, nitride, oxynitride or high-k dielectric. For example, the gate structure separating filling dielectric layer may include silicon oxide. Furthermore, there is no distinct boundary between the gate structure separating filling dielectric layer and the initial second dielectric separating layer 203′ in case that they are fabricated with the same material. After forming the gate structure separating filling dielectric layer, the gate structure separating filling dielectric layer and the initial second dielectric separating layer 203′ remained in the afore-mentioned operation form the second dielectric separating layer 203.

As noted above, FIGS. 13-17 depict a fabrication process of a semiconductor device 1000 having a single side gate transistor (as shown in FIG. 1). The fabrication process of the semiconductor device 1000 having a multi-gate transistor, a gate all around transistor will be described in detail below with reference to FIGS. 18-25, and 26-33.

For example, since the contents involved in the fabrication method 2000 of the semiconductor device having a single side gate transistor as described above may be totally or partially applicable to the fabrication method of the semiconductor device having a multi-gate transistor or a gate all around transistor as described herein, contents related or similar to them will not be described any longer. However, one skilled in the art will appreciate that the semiconductor device 1000 may be formed according to the fabrication method 2000 of the semiconductor device as described above (as shown in FIG. 1) or according to the fabrication method 2000 of the semiconductor device as described below. Based on this, the fabrication method 2000 of the semiconductor device as described in implementation I has the same beneficial effects as the semiconductor device 1000, which will not be described any longer.

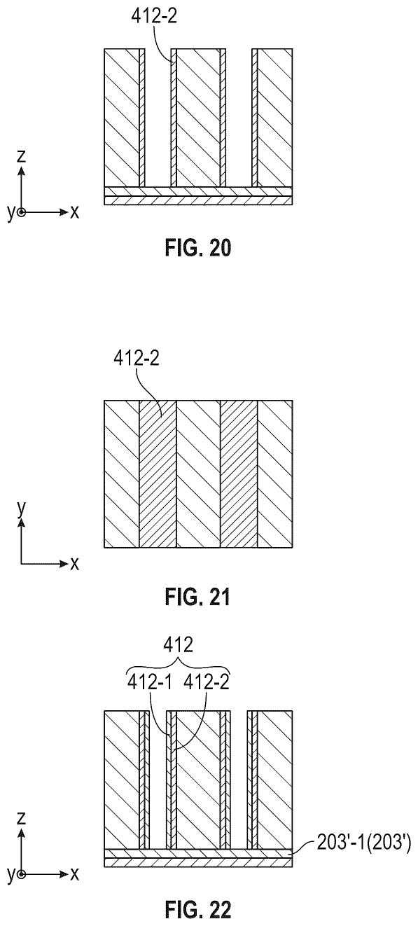

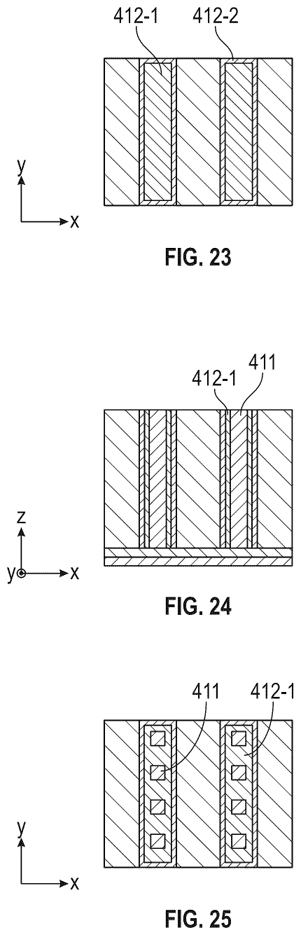

FIG. 18 is a sectional diagram of the structure after forming the third opening 124 in the fabrication method according to an implementation of the present application. FIG. 19 is a top view diagram of the structure after forming the third opening 124 in the fabrication method according to an implementation of the present application. FIG. 20 is a sectional diagram of the structure after forming the gate conductive layer 412-2 in the fabrication method according to an implementation of the present application. FIG. 21 is a top view diagram of the structure after forming the gate conductive layer 412-2 in the fabrication method according to an implementation of the present application. FIG. 22 is a sectional diagram of the structure after forming the gate dielectric layer 412-1 in the fabrication method according to an implementation of the present application. FIG. 23 is a top view diagram of the structure after forming the gate dielectric layer 412-1 in the fabrication method according to an implementation of the present application. FIG. 24 is a sectional diagram of the structure after forming semiconductor body 411 in the fabrication method according to an implementation of the present application. FIG. 25 is a top view diagram of the structure after forming semiconductor body 411 in the fabrication method according to an implementation of the present application.

Referring to FIGS. 13, 18 and 19 in combination, in some implementations of the present application, after operation S2 of forming the bit line 500, the initial second dielectric separating layer 203′ covering the first semiconductor structure 200 and the bit line 500 may be formed with one or more thin film deposition processes which may include, but are not limited to chemical vapor deposition (CVD), physical vapor deposition (PVD), atomic layer deposition (ALD) or any combinations thereof.

In an example, the initial second dielectric separating layer 203′ may include any suitable dielectric material such as oxide, nitride, oxynitride or high-k dielectric. For example, the initial second dielectric separating layer 203′ may include silicon oxide. Furthermore, there is no distinct boundary between the initial second dielectric separating layer 203′ and the first dielectric separating layer 202 in case that they are fabricated with the same material.

In an example, the initial second dielectric separating layer 203′ may include sequentially stacked two parts, a first part of initial second dielectric separating layer 203′-1 and a second part of initial second dielectric separating layer 203′-2. As an example, the first part of initial second dielectric separating layer 203′-1 in direct contact with the bit line 500 may be fabricated with the same material as the subsequently formed gate dielectric layer 412-1, and there is no distinct boundary between them in case that they are fabricated with the same material. In such case, the second part of initial second dielectric separating layer 203′-2 may also be fabricated with the same material as the first dielectric separating layer 202 and there is no distinct boundary between them in case that they are fabricated with the same material.

As shown in FIGS. 18-19, after forming the initial second dielectric separating layer 203′, the third opening 124 that may extend to the first part of initial second dielectric separating layer 203′-1 in z direction in the second part of initial second dielectric separating layer 203′-2 may be formed with for example dry etching process or a combination of dry etching process and wet etching process, or by implementing other manufacturing processes such as patterning processes including photolithography, cleaning and chemical mechanical polishing.

As shown in FIGS. 18-23, after the third opening 124 is formed, the gate structure 412 is formed on inner wall of the third opening 124 with one or more thin film deposition processes which may include, but are not limited to chemical vapor deposition (CVD), physical vapor deposition (PVD), atomic layer deposition (ALD) or any combinations thereof.

In an example, as shown in FIGS. 18-21, forming the gate structure 412 may include: forming a gate conductive layer 412-2 on inner wall of the third opening 124 with one or more thin film deposition processes. The gate conductive layer 412-2 may include a gate adhesive layer (not shown) and a gate metal layer over and in contact with the gate adhesive layer. The gate adhesive layer may include, but is not limited to titanium, titanium nitride, tantalum, tantalum nitride, etc. In addition, the gate metal layer may include any suitable conductive material. For example, the gate metal layer may include, but is not limited to tungsten (W), cobalt (Co), copper (Cu), aluminum (Al), etc.

It is to be noted that in the process of forming the gate conductive layer 412-2, it may be formed by forming an initial gate conductive layer first on side wall and bottom surface of the third opening 124 and then removing the part of the initial gate conductive layer on the bottom surface by processes such as etching.

As shown in FIGS. 20-23, after forming the gate conductive layer 412-2, the gate dielectric layer 412-1 may be formed on surface of the gate conductive layer 412-2 with one or more thin film deposition processes which may include, but are not limited to chemical vapor deposition (CVD), physical vapor deposition (PVD), atomic layer deposition (ALD) or any combinations thereof.

In an example, the gate dielectric layer 412-1 may include any suitable dielectric material such as silicon oxide, silicon nitride, silicon oxynitride or high-k dielectric. For example, the gate dielectric layer 412-1 may include silicon oxide. Furthermore, the gate adhesive layer is configured to block the diffusion of metal material in the gate metal layer and also to enhance the adhesion between the gate metal layer and the gate dielectric layer 412-1.

In an implementation of the present application, as shown in FIGS. 22-25, after forming the gate structure 412, the semiconductor body 411 may be formed in the remaining space of the third opening 124 (as shown in FIG. 18).

As an example, the semiconductor body 411 may be formed with thin film fabrication processes. For example, the semiconductor body 411 may be an oxide semiconductor layer containing at least one of indium, gallium or zinc. In an example, the semiconductor body 411 is formed with low temperature deposition process. The process temperature T for low temperature deposition may satisfy: 200° C.≤ST≤300° C. For example, due to its relatively high carrier mobility and relatively low leakage current, the semiconductor body formed of low temperature material IGZO may further save the use of semiconductor material, reduce the fabrication cost and reduce the overall size of the semiconductor device.

With the above-described possess, a multi-gate vertical transistor may be formed with dual-side gates. Due to the 3D structure of the semiconductor body 411 and the gate structure 412 surrounding a plurality of side walls of the semiconductor body 411, the multi-gate vertical transistor has a larger gate control area than the single gate transistor so as to better control the channels with a smaller sub-threshold swing.

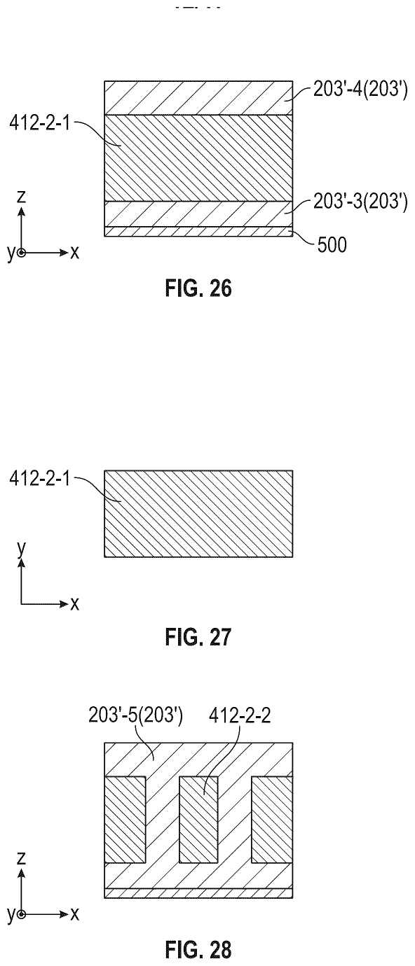

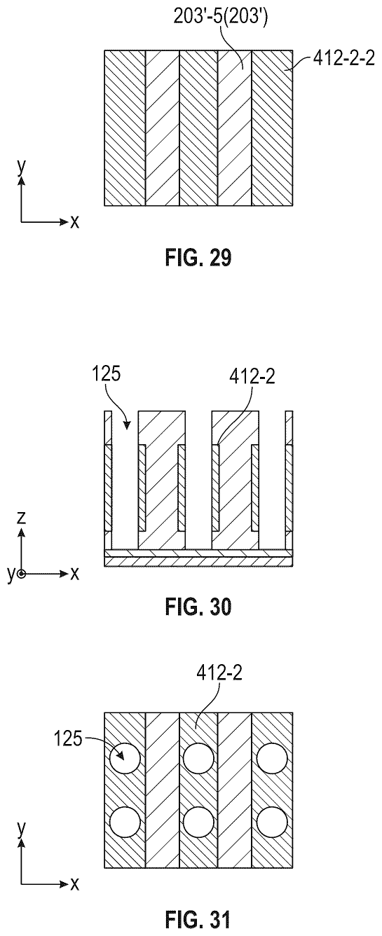

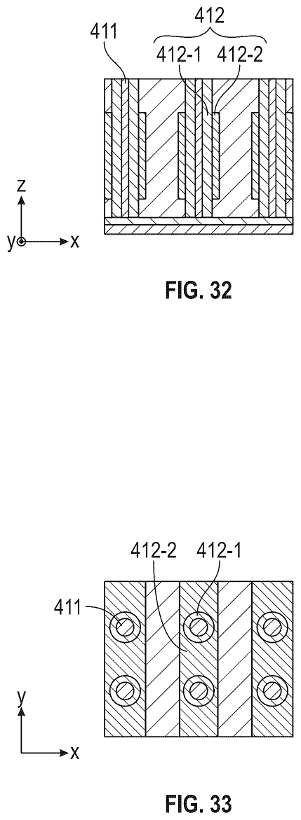

FIG. 26 is a sectional diagram of the structure after forming the first gate conductive layer 412-2-1 in the fabrication method according to an implementation of the present application. FIG. 27 is a top perspective view diagram of the structure after forming the first gate conductive layer 412-2-1 in the fabrication method according to an implementation of the present application. FIG. 28 is a sectional diagram of the structure after forming the second gate conductive layer 412-2-2 in the fabrication method according to an implementation of the present application. FIG. 29 is a top perspective view diagram of the structure after forming the second gate conductive layer 412-2-2 in the fabrication method according to an implementation of the present application. FIG. 30 is a sectional diagram of the structure after forming the gate conductive layer 412-2 in the fabrication method according to an implementation of the present application. FIG. 31 is a top perspective view diagram of the structure after forming the gate conductive layer 412-2 in the fabrication method according to an implementation of the present application. FIG. 32 is a sectional view of the structure after forming semiconductor body 411 in the fabrication method according to an implementation of the present application. FIG. 33 is a top perspective view diagram of the structure after forming semiconductor body 411 in the fabrication method according to an implementation of the present application.

Referring to FIGS. 13, 26 and 27 in combination, in some implementations of the present application, after operation S2 of forming the bit line 500, the initial second dielectric separating layer 203′ covering the first semiconductor structure 200 and the bit line 500 and the first gate conductive layer 412-2-1 may be formed with one or more thin film deposition processes which may include, but are not limited to chemical vapor deposition (CVD), physical vapor deposition (PVD), atomic layer deposition (ALD) or any combinations thereof.

In an example, the initial second dielectric separating layer 203′ may include two parts, a third part of initial second dielectric separating layer 203′-3 and a fourth part of initial second dielectric separating layer 203′-4. The initial second dielectric separating layer 203′ may include any suitable dielectric material such as oxide, nitride, oxynitride or high-k dielectric. For example, the initial second dielectric separating layer 203′ may include silicon oxide. As an example, the initial second dielectric separating layer 203′ may be fabricated with the same material as the first dielectric separating layer 202 and there is no distinct boundary between them in case that they are fabricated with the same material.

In an example, the third part of initial second dielectric separating layer 203′-3 and the fourth part of initial second dielectric separating layer 203′-4 are fabricated of the same material and there is no distinct boundary between them in case that they are fabricated with the same material.

In an example, with the above-described process, the third part of initial second dielectric separating layer 203′-3 is formed on at least the surface of the bit line 500; then the first gate conductive layer 412-2-1 is formed on the surface of the third part of initial second dielectric separating layer 203′-3; and then the fourth part of initial second dielectric separating layer 203′-4 is formed on the first gate conductive layer 412-2-1.

In an example, the first gate conductive layer 412-2-1 may include a first gate adhesive layer (not shown) and a first gate metal layer over and in contact with the first gate adhesive layer. The first gate adhesive layer may include, but is not limited to titanium, titanium nitride, tantalum, tantalum nitride, etc. In addition, the first gate metal layer may include any suitable conductive material. For example, the gate metal layer may include, but is not limited to tungsten (W), cobalt (Co), copper (Cu), aluminum (Al), etc.

As shown in FIGS. 26-29, the second gate conductive layer 412-2-2 may be formed with for example dry etching process or a combination of dry etching process and wet etching process, or by implementing other manufacturing processes such as patterning processes including photolithography, cleaning and chemical mechanical polishing to remove partial first gate conductive layer 412-2-1. In addition, the resultant space after removing partial first gate conductive layer 412-2-1 may be filled with a fifth part of initial second dielectric separating layer 203′-5 with one or more thin film deposition processes to separate the plurality of second gate conductive layers 412-2-2. In an example, the fifth part of initial second dielectric separating layer 203′-5 may be formed with the same material as the third part of initial second dielectric separating layer 203′-3 and the fourth part of initial second dielectric separating layer 203′-4 and there is no distinct boundary among them in case that they are fabricated with the same material.

As shown in FIGS. 28-31, the fourth opening 125 extending in z direction and the gate conductive layer 412-2 may be formed with for example dry etching process or a combination of dry etching process and wet etching process, or by implementing other manufacturing processes such as patterning processes including photolithography, cleaning and chemical mechanical polishing to remove partial second gate conductive layer 412-2-2.

As shown in FIGS. 30-33, the gate dielectric layer 412-1 and the semiconductor body 411 may be formed in the fourth opening 125 with one or more thin film deposition processes which may include, but are not limited to chemical vapor deposition (CVD), physical vapor deposition (PVD), atomic layer deposition (ALD) or any combinations thereof.

In an example, the gate dielectric layer 412-1 may include any suitable dielectric material such as silicon oxide, silicon nitride, silicon oxynitride or high-k dielectric. For example, the gate dielectric layer 412-1 may include silicon oxide. Furthermore, the gate adhesive layer is configured to block the diffusion of metal material in the gate metal layer and also to enhance the adhesion between the gate metal layer and the gate dielectric layer 412-1.

In addition, the semiconductor body 411 may be an oxide semiconductor layer containing at least one of indium, gallium or zinc. In an example, the semiconductor body 411 is formed with low temperature deposition process. The process temperature T for low temperature deposition may satisfy: 200° C.≤ST≤300° C. For example, due to its relatively high carrier mobility and relatively low leakage current, the semiconductor body formed of low temperature material IGZO may further save the use of semiconductor material, reduce the fabrication cost and reduce the overall size of the semiconductor device.

With the above process, a gate all around transistor may be formed. Due to the 3D structure of the semiconductor body 411 and the gate structure 412 surrounding all side walls of the semiconductor body 411, the gate all around vertical transistor has a larger gate control area than the single gate transistor so as to better control the channels with a smaller sub-threshold swing.

FIG. 26 is a sectional diagram of the structure after forming the first gate conductive layer 412-2-1 in the fabrication method according to an implementation of the present application. FIG. 27 is a top perspective view diagram of the structure after forming the first gate conductive layer 412-2-1 in the fabrication method according to an implementation of the present application. FIG. 28 is a sectional diagram of the structure after forming the second gate conductive layer 412-2-2 in the fabrication method according to an implementation of the present application. FIG. 29 is a top perspective view diagram of the structure after forming the second gate conductive layer 412-2-2 in the fabrication method according to an implementation of the present application. FIG. 30 is a sectional diagram of the structure after forming the gate conductive layer 412-2 in the fabrication method according to an implementation of the present application. FIG. 31 is a top perspective view diagram of the structure after forming the gate conductive layer 412-2 in the fabrication method according to an implementation of the present application. FIG. 32 is a sectional diagram of the structure after forming semiconductor body 411 in the fabrication method according to an implementation of the present application. FIG. 33 is a top perspective view diagram of the structure after forming semiconductor body 411 in the fabrication method according to an implementation of the present application.

Furthermore, referring to FIG. 1, after forming the memory cells 400, a power layer 930 and a second interconnect structure 920 may also be formed over the memory cells 400. The power layer 930 and the second interconnect structure 920 may be fabricated with relevant processes and according to practical requirements, which will not be described any longer.

In an example, the second interconnect structure 920 may extend in z direction to connect the power layer 930 and the peripheral circuit of the first semiconductor structure 200.

In addition, the semiconductor device 1000 further includes a first pad 940 connecting external electrical signals, which may be connected with the power layer 930 or the peripheral circuit in the first semiconductor structure 200. The first pad 940 may be fabricated with relevant processes and according to practical requirements, which will not be described any longer.

In an example, the first pad 940 is disposed in the second semiconductor structure 300 to increase locations for the interconnect structure layout in the semiconductor device 1000 and improve flexibility of the interconnect structure layout.

### Implementation II

As shown in FIG. 2, as another example, in the semiconductor device 1000, the storage cells 402 are closer to the first semiconductor structure 200 than the transistor 401.

Processes of operations of the above-described fabrication method 2000 in implementation II will be described in detail below in connection with FIGS. 34-38 to form the semiconductor device 1000 shown in FIG. 2.

Since the contents involved in the fabrication method 2000 of the semiconductor device as described above in implementation I may be totally or partially applicable to the fabrication method of the semiconductor device as described herein (implementation II), contents related or similar to them will not be described any longer. However, one skilled in the art will appreciate that the semiconductor device 1000 may be formed according to the fabrication method 2000 of the semiconductor device as described in implementation I (as shown in FIG. 1) or according to the fabrication method 2000 of the semiconductor device as described in implementation II (as shown in FIG. 2). Based on this, the fabrication method 2000 of the semiconductor device as described in both implementations I and II have the same beneficial effects as the semiconductor device 1000, which will not be described any longer.

### Operation S2

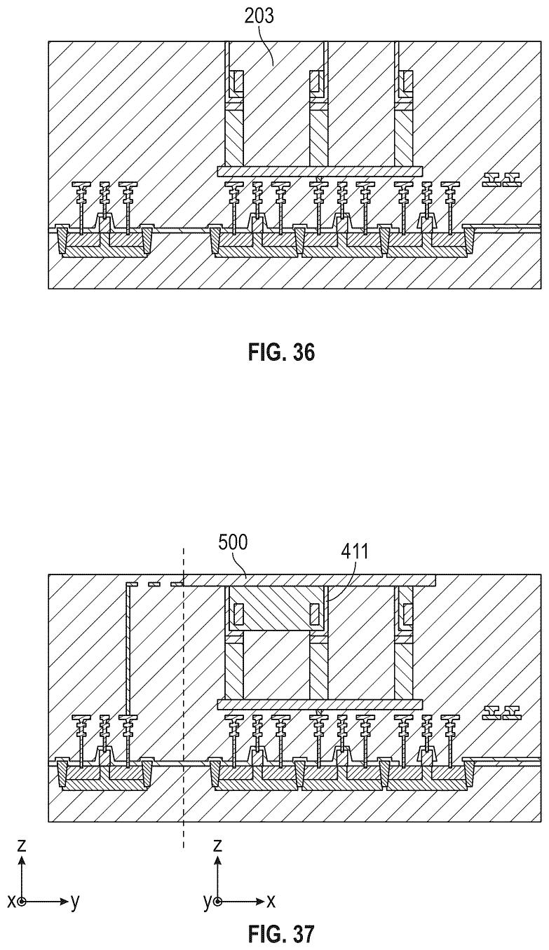

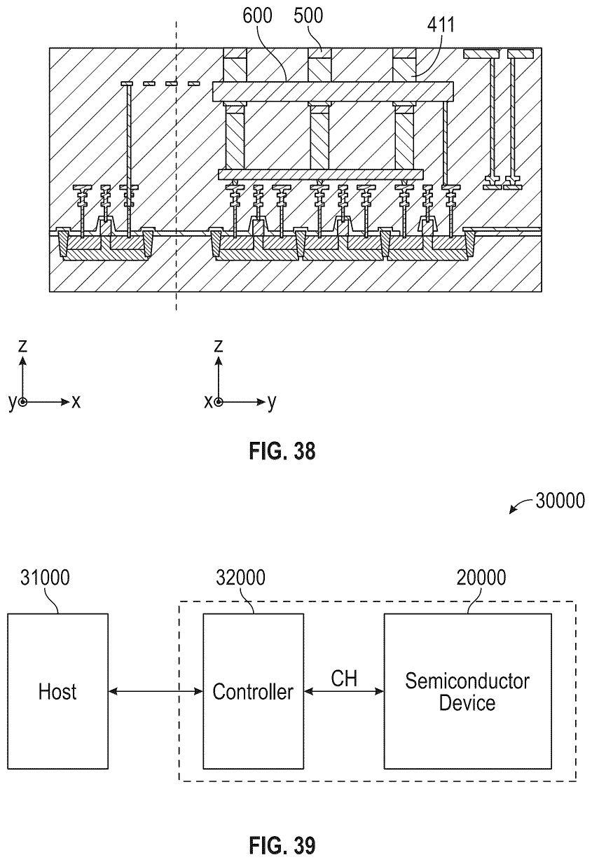

FIG. 34 is a sectional diagram of the structure after forming the storage cells 402 in the fabrication method according to an implementation of the present application. FIG. 35 is a sectional diagram of the structure after forming the transistor 401 in the fabrication method according to an implementation of the present application. FIG. 36 is a sectional diagram of the structure after forming the second dielectric separating layer 203 in the fabrication method according to an implementation of the present application. FIG. 37 is a sectional diagram of the structure after forming the bit line 500 and word line 600 in the fabrication method according to an implementation of the present application. FIG. 38 is a sectional diagram of the resultant structure after rotating the intermediate shown in FIG. 37 by 90° in x-y plane.

As shown in FIGS. 2 and 34-38, the operation S2 of forming a second semiconductor structure in direct contact with the first semiconductor structure on the first semiconductor structure, wherein the second semiconductor structure includes a plurality of memory cells connected with the first peripheral circuit, may include for example: forming the first dielectric layer 301 on the first semiconductor structure 200; forming memory cells on the first dielectric layer 301; and forming a semiconductor body 411 connected with storage cells 402 on the storage cells 402, wherein the semiconductor body 411 extends in z direction.

In an example, as shown in FIG. 34, in an implementation of the present application, the first dielectric layer 301 may be formed with one or more thin film deposition processes which may include, but are not limited to chemical vapor deposition (CVD), physical vapor deposition (PVD), atomic layer deposition (ALD) or any combinations thereof. The first dielectric layer 301 may include any suitable dielectric material such as oxide, nitride, oxynitride or high-k dielectric. For example, the first dielectric layer 301 may include silicon oxide.

In an example, the surface of the first dielectric layer 301 is treated with any suitable planarization process such as at least one of grinding or chemical mechanical polishing such that the treated first dielectric layer 301 has a relatively flat surfaces, thereby facilitating forming storage cells 402 on the flat surface. The storage cells 402 may adopt relevant structure and may be fabricated with relevant processes and according to practical requirements, which will not be described any longer in the present application.

In an example, in some implementations, considering a DRAM as an example, a storage cell 402 may include a capacitor, and a plurality of storage cells 402 may be arranged in form of a two-dimensional array. In an example, in some implementations, considering a PCM element as an example, the storage cell 402 may include respective PCM unit with different resistivities in amorphous and crystalline phases for storing. For example, it includes a chalcogenide alloy. In an example, in some implementations, considering a FRAM as an example, a storage cell 402 may include a ferroelectric capacitor. This is not limited in the present application.

Furthermore, after forming the storage cells 402, the initial second dielectric separating layer 203′ covering at least the storage cells 402 may also be formed with one or more thin film deposition processes which may include, but are not limited to chemical vapor deposition (CVD), physical vapor deposition (PVD), atomic layer deposition (ALD) or any combinations thereof.

In an example, the initial second dielectric separating layer 203′ may be fabricated with the same material as the first dielectric separating layer 202 and there is no distinct boundary between them in case that they are fabricated with the same material.

It is to be noted that in FIGS. 34-38 herein, only the numbers and locations of memory cells and peripheral circuit are illustrated. However, it is appreciated that the memory cells and peripheral circuit shown in the figures and related contents herein are only for the purpose of convenient illustration and the present application is not limited thereto. Those skilled in the art can modify the memory cells and peripheral circuit according to the concept of the present disclosure to achieve the same technical effect. Furthermore, in FIG. 34 and other figures in implementation II herein, for convenience of observation, the cross section of the intermediate of the semiconductor device 1000 that is parallel to x-z plane and the cross section that is parallel to y-z plane are disposed on two sides of the dashed-dotted line, respectively.

As shown in FIGS. 34 and 35, after forming the storage cells 402, a semiconductor body 411 connected with storage cells 402 may be formed on the storage cells 402, wherein the semiconductor body 411 extends in z direction.

As an example, the semiconductor body 411 may be formed with thin film fabrication processes. For example, the semiconductor body 411 may be an oxide semiconductor layer containing at least one of indium, gallium or zinc.

In an example, the semiconductor body 411 is formed with low temperature deposition process. The process temperature T for low temperature deposition may satisfy: 200° C.≤T≤300° C. For example, due to its relatively high carrier mobility and relatively low leakage current, the semiconductor body 411 formed of low temperature material IGZO may further save the use of semiconductor material, reduce the fabrication cost and reduce the overall size of the semiconductor device.

Furthermore, as shown in FIG. 35, the gate structure 412 of the transistor 401 is formed with the fabrication process of the single gate transistor as shown in implementation I. It is to be noted that after forming the storage cells 402, the transistor 401 may also be formed with the fabrication process of the multi-gate transistor or gate all around transistor as shown in implementation I.

As shown in FIGS. 35 and 36, after forming the transistor 401, spaces between a plurality of gate structures 412 or spaces remained in the second openings after forming the gate structures 412 may be filled with gate structure separating filling dielectric layers with one or more thin film deposition processes, which may include, but are not limited to chemical vapor deposition (CVD), physical vapor deposition (PVD), atomic layer deposition (ALD) or any combinations thereof.

In an example, the gate structure separating filling dielectric layer may include any suitable dielectric material such as oxide, nitride, oxynitride or high-k dielectric. For example, the gate structure separating filling dielectric layer may include silicon oxide. Furthermore, there is no distinct boundary between the gate structure separating filling dielectric layer and the initial second dielectric separating layer 203′ in case that they are fabricated with the same material. After forming the gate structure separating filling dielectric layer, the gate structure separating filling dielectric layer and the initial second dielectric separating layer 203′ remained in the afore-mentioned operation form the second dielectric separating layer 203.

As shown in FIGS. 36-38, after forming the gate structure 412, a bit line 500 and word line 600 connected with the semiconductor body 411 may also be formed. In an example, the bit line 500 and word line 600 may be formed with the fabrication process shown in implementation I, which will not be described any more in the present application.

In addition, FIG. 39 is a structure diagram of a memory system 30000 according to an implementation of the present application.

As shown in FIG. 39, at least one implementation according to some implementations of the present application further provides a memory system 30000. The memory system 30000 may include a semiconductor device 20000 and a controller 32000. The semiconductor device 20000 may be the same as the semiconductor device described in any of the above implementations and will not be described any longer in the present application. The semiconductor device 20000 may be a two dimensional (2D) semiconductor device or a 3D semiconductor device, or even a part of a 2D semiconductor device or a part of a 3D semiconductor device, and will be described below with respect to a 3D semiconductor device as an example.

As an example, a 3D semiconductor device may include at least one of 3D NAND memory and 3D NOR memory.

The memory system 30000 may include a semiconductor device 20000 and a controller 32000. The semiconductor device 20000 may be the same as the semiconductor device described in any of the above implementations and will not be described any longer in the present application. The controller 32000 may control the semiconductor device 20000 via a channel CH and the semiconductor device 20000 may execute operations based on the control by the controller 32000 in response to the request from the host 31000. The semiconductor device 20000 may receive a command CMD and an address ADDR from the controller 32000 through the channel CH and access regions selected from the memory cell array in response to the address. In other words, the semiconductor device 20000 may execute internal operations corresponding to the command on the regions selected by the address.

In some implementations, the 3D memory system may be implemented as multimedia cards such as universal flash storage (UFS) device, solid state hard disk (SSD), MMC, eMMC, RS-MMC and micro-MMC, secure digital cards such as SD, mini-SD and micro-SD, storage devices of Personal Computer Memory Card International Association (PCMCIA) type, storage devices of peripheral component interconnect (PCI), storage devices of PCI Express (PCI-E) type, compact flash (CF) cards, smart media cards or memory sticks etc. The memory system provided in the present application is provided with the semiconductor device as provided in the present application and therefore has the same beneficial effects as the semiconductor device, which will not be described any longer herein.

Although example fabrication methods and structures of a semiconductor device have been described herein, it is appreciated that one or more features may be omitted from, substituted or added to the structure of the semiconductor device. Furthermore, materials illustrated for layers are only examples.

The description above is only for the purpose of explaining implementations and technical principles of the present application. It will be appreciated by those skilled in the art that the scope claimed by the present application is not limited to technical solutions composed of selected combinations of the above-mentioned technical features, and instead will cover any other technical solutions composed of any combinations of the above-mentioned features and their equivalents without departing from the present technical concept. For example, technical solutions resulted from substitutions of the above-mentioned features by technical features of similar functions (including, but not limited to, those disclosed in the present application) still fall within the scope of the present disclosure.

The description above is only for the purpose of explaining implementations and technical principles of the present application. It will be appreciated by those skilled in the art that the scope claimed by the present application is not limited to technical solutions composed of particular combinations of the above-mentioned technical features, and instead will cover any other technical solutions composed of any combinations of the above-mentioned features and their equivalents without departing from the present technical concept. For example, technical solutions resulted from substitutions of the above-mentioned features by technical features of similar functions (including, but not limited to, those disclosed in the present application) still fall within the scope of the present disclosure.

What is claimed is:

1. A semiconductor device, comprising:
a first semiconductor structure; and
a second semiconductor structure disposed on a side of the first semiconductor structure in a first direction and in direct contact with the first semiconductor structure, wherein:
the second semiconductor structure comprises a plurality of memory cells, and the first semiconductor structure comprises a first peripheral circuit connected with the plurality of memory cells; and
in a plane perpendicular to the first direction, at least a portion of the first peripheral circuit is located directly below the plurality of memory cells, wherein the first peripheral circuit includes at least one of a driving structure and a sensing structure.

2. The semiconductor device of claim 1, wherein,
the first semiconductor structure further comprises a first interconnect structure, wherein the first interconnect structure is located on a side of the first peripheral circuit close to the second semiconductor structure in the first direction, and the first interconnect structure connects the first semiconductor structure and the second semiconductor structure; and
the second semiconductor structure further comprises a power layer and a second interconnect structure, wherein the second interconnect structure connects the power layer and the first semiconductor structure.

3. The semiconductor device of claim 2, wherein,
the power layer is located on a side of the plurality of memory cells away from the first semiconductor structure in the first direction.

4. The semiconductor device of claim 1, wherein,
the semiconductor structure comprises word lines and bit lines connected with the plurality of memory cells; and
the driving structure comprises a word line driving structure connected with the word lines, and the sensing structure comprises a bit line sensing amplifying structure connected with the bit lines.

5. The semiconductor device of claim 4, wherein,
the semiconductor structure further comprises a word line contact structure connecting the word lines and the word line driving structure and a bit line contact structure connecting the bit lines and the bit line sensing amplifying structure, and
wherein at least one of the word line contact structure and the bit line contact structure extends in the first direction.

6. The semiconductor device of claim 4, wherein,
the bit lines extends in a second direction, the word lines extends in a third direction, wherein the first direction, the second direction and the third direction are perpendicular to each other, and
wherein in a plane parallel to the second direction and the third direction, the driving structures and the sensing structures are alternately disposed in the second direction or the third direction.

7. The semiconductor device of claim 4, wherein,
the bit lines extends in a second direction, the word lines extends in a third direction, wherein the first direction, the second direction and the third direction are perpendicular to each other, and
wherein in a plane parallel to the second direction and the third direction, at least one of:
a plurality of the driving structures are distributed symmetrically; or
a plurality of the sensing structures are distributed symmetrically.

8. The semiconductor device of claim 1, wherein,
at least one of the plurality of memory cells comprises a vertical transistor and a storage cell connected with the vertical transistor, and
wherein in the first direction, the vertical transistor is closer to the first semiconductor structure than the storage cell.

9. The semiconductor device of claim 8, wherein,
the vertical transistor comprises a thin film transistor.

10. The semiconductor device of claim 8, wherein,
the vertical transistor comprises a semiconductor body extending in the first direction, wherein the semiconductor body comprises an oxide semiconductor layer.

11. A method of fabricating a semiconductor device, comprising:
forming a first semiconductor structure on a substrate, wherein the first semiconductor structure comprises a first peripheral circuit comprising at least one of a driving structure and a sensing structure; and
forming a second semiconductor structure in direct contact with the first semiconductor structure on the first semiconductor structure, wherein the second semiconductor structure comprises a plurality of memory cells connected with the first peripheral circuit,
wherein in a plane parallel to the substrate, the first peripheral circuit is located directly below the plurality of memory cells.

12. The method of claim 11, wherein forming the second semiconductor structure in direct contact with the first semiconductor structure over the first semiconductor structure comprises:
forming a first dielectric layer over the first semiconductor structure;
forming storage cells on the first dielectric layer;
forming semiconductor bodies connected with the storage cell over the storage cell,
wherein the semiconductor bodies extend in a first direction perpendicular to the substrate.

13. The method of claim 11, wherein forming the second semiconductor structure in direct contact with the first semiconductor structure over the first semiconductor structure comprises:
forming bit lines over the first semiconductor structure;
forming semiconductor bodies and gate structures connected with the semiconductor bodies over the bit lines, wherein the semiconductor bodies extends in a first direction perpendicular to the substrate; and
forming storage cells connected with and over the semiconductor bodies.

14. A semiconductor device, comprising:
a first semiconductor structure; and
semiconductor bodies disposed on a side of the first semiconductor structure in a first direction, wherein:
each of the semiconductor bodies comprises a first section and a second section connected with each other, wherein the first section extends in the first direction, the second section extends in a direction perpendicular to the first direction and directly contacts the first semiconductor structure.

15. The semiconductor device of claim 14, wherein,
the first semiconductor structure comprises a first peripheral circuit located directly below a plurality of the semiconductor bodies, wherein the first peripheral circuit comprises at least one of a driving structure and a sensing structure.

16. The semiconductor device of claim 15, wherein,
the semiconductor structure further comprises a first interconnect structure, a power layer and a second interconnect structure,
wherein the first interconnect structure is located on a side of the first peripheral circuit close to the semiconductor bodies in the first direction;
the power layer is located on a side of the semiconductor bodies away from the first semiconductor structure in the first direction; and
the second interconnect structure connects the power layer and the first semiconductor structure.

17. The semiconductor device of claim 14, wherein,
the semiconductor structure further comprises gate structures and bit lines,
wherein the gate structures are located at the first section and the second section; and
the bit lines are located on a side of the second section away from the first section, or the bit lines are located on a side of the first section away from the second section.

18. The semiconductor device of claim 17, wherein,
the semiconductor structure further comprises word lines connected with the gate structures and extending in a third direction, wherein the first direction and the third direction are perpendicular to each other; and
the first semiconductor structure comprises a first peripheral circuit, wherein the first peripheral circuit comprises at least one of a driving structure and a sensing structure, wherein the driving structure comprises a word line driving structure connected with the word lines, and the sensing structure comprises a bit line sensing amplifying structure connected with the bit lines.

19. The semiconductor device of claim 18, wherein,
the semiconductor structure further comprises a word line contact structure connecting the word lines and the word line driving structure and a bit line contact structure connecting the bit lines and the bit line sensing amplifying structure, and
wherein at least one of the word line contact structure and the bit line contact structure extends in the first direction.

20. The semiconductor device of claim 14, wherein,
each of the semiconductor bodies comprises an oxide semiconductor layer.
